(19) United States
(12) Patent Application Publication
(10) Pub. No.: US 2024/0229221 A1
(43) Pub. Date: Jul. 11, 2024

(54) PROCESS FOR THE PREPARATION OF ALUMINUM SCANDIUM NITRIDE FILMS

(71) Applicant: YEDA RESEARCH AND DEVELOPMENT CO. LTD., Rehovot (IL)

(72) Inventors: Igor LUBOMIRSKY, Petach-Tikva (IL); David EHRE, Rehovot (IL); Asaf COHEN, Rehovot (IL)

(73) Assignee: YEDA RESEARCH AND DEVELOPMENT CO. LTD., Rehovot (IL)

(21) Appl. No.: 18/559,576

(22) PCT Filed: May 12, 2022
(86) PCT No.: PCT/IL2022/050498

§ 371 Date: Nov. 8, 2023

(30) Foreign Application Priority Data
May 12, 2021 (IL) 283142

(51) Int. Cl. C23C 14/06; C23C 14/00; C23C 14/02; H10N 30/06; H10N 30/076; H10N 30/079; H10N 30/20

(52) U.S. Cl. CPC C23C 14/0617; C23C 14/0036; C23C 14/021; C23C 14/025; H10N 30/06; H10N 30/076; H10N 30/079; H10N 30/2042

(57) ABSTRACT

This invention provides a process for the preparation of aluminum scandium nitride films. This invention further provides Caluminum scandium nitride films and layers, and devices and systems comprising aluminum scandium nitride films.

### FIELD OF THE INVENTION

This invention provides a process for the preparation of oriented aluminum scandium nitride films. This invention further provides aluminum scandium nitride films and layers, and devices and systems comprising aluminum scandium nitride films.

### BACKGROUND OF THE INVENTION

Devices which utilize piezoelectricity for operation, are common in a wide range of fields, with an ever-increasing demand. Scandium-doped aluminum nitride, (AlSc)N is a lead-free, biocompatible, environmentally friendly, piezoelectric, dielectric material. (AlSc)N thin films are one of the most promising candidates as an active material in piezoelectric MEMS (micro-electro-mechanical systems). (AlSc)N thin films have chemical stability, excellent thermal conductivity, large elastic modulus and compatibility with Si-based microfabrication. Piezoelectric thin-film based Si-integrated MEMS hold a big promise for a number of vital technologies, ranging from vibrational gyroscopes and switches to bulk piezoelectric resonators and tunable capacitors. The main obstacle to mass use of piezoelectric MEMS is incompatibility of the most common piezoelectric materials (Pb-based, Bi-based or [Li, Na, K]-containing materials) with Si-microfabrication.

(AlSc)N films are among the very few piezoelectric materials that can be easily integrated into Si microfabrication. Although (AlSc)N films have considerably lower piezoelectric coefficients than the most commonly used piezoelectric materials, for instance, lead zirconium titanate (PZT), (AlSc)N films can withstand high electric field, generating stress in excess of 20 MPa. This is well comparable to PZT, which is rarely driven to stress above 100 MPa. In addition, the dielectric constant of (AlSc)N is <10, while that of PZT is >1000. This implies that devices based on (AlSc)N have a high electrical impedance, which greatly simplifies driving circuitry. In this view, (AlSc)N is a primary candidate for large-scale piezoelectric MEMS.

The main problem with practical applications of (AlSc)N for MEMS is the absence of a reliable way to deposit films above 1 μm. This limits the force (product of stress and thickness) that films can generate. Moreover, in many cases the surface of the deposited films is not smooth, containing segregated nanocrystals of ScN, serving as a starting point for mechanical failure.

To ensure the piezoelectric potential of (AlSc)N thin films, a uniform (001) film texture is required. However, depositing fully oriented (001) films without ScN segregation remains challenging. This is because ScN and AlN are immiscible in bulk form; such immiscibility is the driving force for their segregation and loss of orientation during thin film deposition. The classical approach for deposition of (AlSc)N thin films is based on the preliminary (111)-textured seeding layers, generally Pt, Au or Mo. These metals are chemically inert with respect to (AlSc)N at standard deposition temperatures.

Assuming that to be unavoidable, local compressive stress induced by densely spaced growth dislocations developing on continuous nucleation layers is a contributing factor in promoting segregation, a different approach is required for the preparation of (AlSc)N thin films.

While doping AlN with Sc increases the piezoelectric coefficient of AlN, it presents considerable difficulties with film preparation because, as bulk solids with completely different structures and large differences in cation radii, ScN (rock salt) and AlN (Wurtzite) are completely immiscible. As a result, (Al,Sc)N alloy is inherently thermodynamically unstable and prone to phase segregation. Film preparation is further complicated by the demand of growing polar (001) or (001) out-of-plane texture, which is achieved using a seeding layer.

To induce growth of textured (Al,Sc)N films, the seeding layer must satisfy two critical parameters; a) close epitaxial match b) low surface roughness to prevent secondary nucleation. The most common solution uses reactive sputtering onto textured seeding layers of (111)FCC or (110)BCC metals, e.g., Au, Pt, or Mo. These metals are chemically inert towards N₂ and (Al,Sc)N, and have a lattice mismatch to the (001) plane of (Al,Sc)N of 7.5%, 10.8% and 12.4% respectively. It was observed that even when (Al,Sc)N films begin to grow with strong [001] texture, orientation is often lost once film thickness approaches a few hundred nm. The loss of orientation is attributed to local stress/strain induced by the lattice mismatch during deposition and high substrate surface roughness. These facts, combined with the inherent thermodynamic instability of (Al,Sc)N, are theorized to promote Sc segregation to the grain boundaries, further accelerating phase segregation and/or loss of orientation. Allegedly (001) oriented α-Ti and (111) TiN should provide a better seeding layer than the FCC and BCC metals, since they are a better epitaxial match to (Al,Sc)N. However, previous (Al,Sc)N depositions on Ti or TiN seeding layers yielded unsatisfactory results.

### SUMMARY OF THE INVENTION

In one embodiment, the present invention is directed toward a process for the preparation of an AlₓSc₁₋ₓN film. In one embodiment, the process comprising replacing a chemically inert seeding layer, with an intermediate layer. In one embodiment, the chemically inert seeding layer comprises Ti, and the intermediate seeding layer comprises TiN. In one embodiment, the nitride of the TiN layer is formed by reaction of nitrogen plasma with a Ti seeding layer. In one embodiment, the lattice mismatch of Ti to (Al,Sc)N is decreased when a TiN seeding layer is present. In one embodiment, the presence of the TiN layer allows growth of a AlₓSc₁₋ₓN film with improved properties, especially in view of its use as a piezoelectric material. Embodiments of the present invention are directed to a new polycrystalline AlₓSc₁₋ₓN material, and to a piezoelectric device comprising AlₓSc₁₋ₓN.

In one embodiment, this invention provides a process for the preparation of AlₓSc₁₋ₓN film, said process comprising:
a) providing a substrate;
b) producing a first layer comprising Ti on said substrate;
c) producing a TiN layer on said first layer;
d) producing an AlₓSc₁₋ₓN layer on said TiN layer, wherein said AlₓSc₁₋ₓN layer is in contact with said TiN.

In one embodiment, steps (b)-(d) are performed in a sputtering chamber. In one embodiment, step (b) is conducted by sputtering Ti. In one embodiment, step (c) comprises exposing the first layer to nitrogen gas, thus forming a TiN layer. In one embodiment, step (d) of producing said AlₓSc₁₋ₓN layer comprises sputtering AlₓSc₁₋ₓ on said TiN layer in the presence of nitrogen gas. In one embodiment, step (d) is performed after step (c) or wherein steps (c) and (d) are performed simultaneously or wherein steps (c) and (d) are performed at least partially at the same time.

In one embodiment, step (c) comprises exposing said first layer to a temperature ranging between 25° C. and 600° C. and to nitrogen gas.

In one embodiment, when producing the first layer (step (b)), the sputtering chamber does not comprise nitrogen gas.

In one embodiment, when producing the TiN layer and the AlₓSc₁₋ₓN layer (steps (c) and (d)) the sputtering chamber comprises nitrogen gas.

In one embodiment, x in AlₓSc₁₋ₓN ranges between 0.57≤x≤1.

In one embodiment, AlₓSc₁₋ₓN is Al_{0.75}Sc_{0.25}N or Al_{0.75}Sc_{0.25}N or Al_{0.7}Sc_{0.3}N. In one embodiment, the thickness of said AlₓSc₁₋ₓN layer is greater than 0.8 μm. In one embodiment, prior to step (b), said substrate is cleaned. In one embodiment, the cleaning comprises the use of:
organic or inorganic solvent; and/or
organic or inorganic acid; and/or
gas plasma.

In one embodiment:
step (b) is conducted at room temperature;
step (c) is conducted at a temperature ranging between 25° C. to 400° C.; and
step (d) is conducted at a temperature ranging between 250° C. to 600° C.

In one embodiment:
step (b) is conducted under argon;
step (c) is conducted under a gas comprising nitrogen and argon; and
step (d) is conducted under a gas comprising nitrogen and argon.

In one embodiment, step (b), step (c), step (d) or any combination thereof is conducted at a pressure lower than 1 atm.

In one embodiment, the process further comprising producing a top layer comprising an electrically conductive material on said AlₓSc₁₋ₓN layer. In one embodiment, the electrically conductive material is selected from Cu, Ag, Au, Pt, Pd, Ni, Al, Ta and Ti or a combination thereof. In one embodiment, the top layer comprises Ti. In one embodiment, the first layer and the top layer are used as electrodes. In one embodiment, the electrodes are independently connected to a power supply.

In one embodiment, the thickness of the combined Ti layer and TiN layer is between 50-300 nm.

In one embodiment, this invention provides a Ti/TiN layer made by the process as described herein above, wherein the thickness of the Ti/TiN layer is ranging between 50-300 nm. In one embodiment, this invention provides an AlₓSc₁₋ₓN layer made by the process as described herein above.

In one embodiment, for the AlₓSc₁₋ₓN layer:
the internal stress is in the range of 60-300 MPa; or
the layer has c-axis (001) normal to the substrate; or
a combination thereof.

In one embodiment, this invention provides a polycrystalline AlₓSc₁₋ₓN film wherein:
the orientation of said film is 001/002; or
the piezoelectric coefficient of said film ranges between 1.0 C/m² and 4.0 C/m²; or
the compressive stress of said film ranges between 5 MPa and 500 MPa; or
any combination thereof.

In one embodiment, the thickness of the polycrystalline AlₓSc₁₋ₓN film is greater than 0.8 μm.

In one embodiment, the thickness of the AlₓSc₁₋ₓN film ranges between 0.8 μm and 10 μm or between 0.5 μm and 4 μm.

In one embodiment, this invention provides a piezoelectric device comprising:
a substrate;
a first layer comprising Ti on said substrate;
TiN in contact with said Ti layer;
a layer comprising AlₓSc₁₋ₓN in contact with said TiN; and
a top layer comprising an electrically conductive material on said AlₓSc₁₋ₓN layer.

In one embodiment, the electrically conductive material is selected from Cu, Ag, Au, Pt, Pd, Ni, Al, Ta and Ti or a combination thereof.

In one embodiment, the piezoelectric device is operable under electric fields of up to 100 Vpp.

In one embodiment, this invention provides a cantilever comprising a AlₓSc₁₋ₓN layer as described herein above. In one embodiment, this invention provides a cantilever comprising a piezoelectric device as described herein above.

In one embodiment, this invention provides a micro electro-mechanical system (MEMS) comprising an AlₓSc₁₋ₓN layer as described herein above. In one embodiment, this invention provides a micro electro-mechanical system (MEMS) comprising a piezoelectric device as described herein above.

In one embodiment, this invention provides a process for the preparation of AlₓSc₁₋ₓN film, said process comprising:
a. providing a substrate;
b. producing a first layer comprising Ti on said substrate;
c. exposing said first layer to high temperature and nitrogen gas; and
d. producing an upper layer comprising AlₓSc₁₋ₓN.

In one embodiment, this invention provides a piezoelectric device comprising:
a. a substrate;
b. a first layer comprising Ti on said substrate;
c. an upper layer comprising AlₓSc₁₋ₓN; and
d. a top layer comprising an electrically-conductive material on said upper layer.

In one aspect, the piezoelectric device further comprising TiN on said first layer.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIGS. 1A-1D illustrates structures as follows. FIG. 1A illustrates a cubic structure of TiN. FIG. 1B illustrates a TiN (111) plane. FIG. 1C illustrates a hexagonal Wurtzite structure of AlN and a (001) plane from a top-down view. FIG. 1D illustrates three surface layer representations of small epitaxial mismatches.

FIGS. 2A-2D show AFM images as follows. FIG. 2A represents an AFM topography of a silicon (100) oriented wafer prior to deposition. FIG. 2B represents the AFM topography after deposition of 50 nm titanium; and FIG. 2C represents the AFM topography after 30 min exposure to N₂ at 400° C. FIG. 2D illustrates an AFM topography scan of the surface of; a) (100) silicon wafer; b) 50 nm thick Ti film deposited on the wafer at 300K; c) the same film following exposure to N₂ plasma at 673K for 30 min.

FIGS. 3A-3D show X-ray and SEM results. FIG. 3A shows X-ray diffraction spectra of 2 μm (AlSc)N films deposited on Ti seed layers at 400° C. (second line from the top), 300° C. (third line from the top) and 250° C. (bottom line). In all samples Si (100) was used as a substrate, first layer Ti 50 mn and (AlSc)N film. The first upper line is an X-Ray of AlN powder reference. FIG. 3B is a SEM imagery of the surface and the cross-section of (AlSc)N films deposited on Ti seed layers at 400° C., 300° C. and 250° C. on (100) silicon.

FIG. 3C shows X-ray diffraction spectra of 3 μm (AlSc)N films deposited on different preliminary layers to inspect effect on orientation at 200° C. ASN4 possesses 300 nm Ti on (100) Si; ASN10 possesses 100 nm aluminum+50 nm Ti on (100) Si; ASN8 possesses 50 nm Ti on (100) Si; and ASN9 possesses 50 nm Ti on borosilicate (Schott) glass. FIG. 3D shows an XRD pattern of Al_{0.75}Sc_{0.25}N films grown on Si(100) wafers, covered with a Ti seeding layer. A progressively narrower (002) peak is observed for final temperature: 673K (blue upper trace); 573K (red middle trace); or 523K (black lower trace).

FIG. 4 shows a pole figure measurement of the (002) peak for 3 μm (AlSc)N film grown on 50 nm Ti seed on (100) silicon substrate.

FIGS. 5A-5C show pole figure measurements. FIG. 5A represents a pole figure measurement of the (002) peak for 3 μm (AlSc)N film grown on 50 nm Ti seed on borosilicate (Schott) glass. FIG. 5B represents a pole figure measurement of the (002) peak for 3 μm (AlSc)N film grown on 50 nm Ti seed on preliminary 100 nm aluminum layer on (100) Silicon. FIG. 5C represents a pole figure measurement of the (002) peak for 3 μm (AlSc)N film grown on 300 nm Ti seed on (100) Silicon.

FIGS. 6A-6B refer to cantilever measurements. FIG. 6A shows a cantilever deflection measurement of (AlSc)N based cantilevers on (100) silicon under 50 Vpp driving voltage at 0.1 Hz. FIG. 6B is a graph showing a linear relation between the magnitude of applied voltage to the magnitude of cantilever displacement.

FIG. 7 is a schematic depiction of a curvature measurement setup used to measure a piezoelectric response of the piezoelectric films. Vertical bending of the cantilever is translated to movement on the CCD.

FIG. 8 shows the curvature of (100) Si and borosilicate glass wafers prior, and after the deposition of (AlSc)N. Upper curve—D263; curve below the upper curve—Si (100); curve above lowest curve—D263 after deposition; lowest curve—Si (100) after deposition.

FIG. 9 represents a schematic cantilever based on piezoelectric (AlSc)N between two titanium electrodes. The (AlSc)N layer grows from TiN seed layers which forms in—situ during deposition.

FIG. 10 shows X-ray diffraction spectra of (Al₇₀, Sc₃₀)N films deposited on Ti seed layers at 250° C. on (100) Silicon.

FIG. 11 represents a pole figure measurement of a (002) peak (Al₇₀, Sc₃₀)N film grown on 50 nm Ti seed on (100) silicon substrate.

FIGS. 12A-12B shows cantilever measurements. FIG. 12A shows a cantilever deflection measurement of (Al₇₀, Sc₃₀)N based cantilevers on (100) silicon under 50 Vpp driving voltage at 0.05 Hz. FIG. 12B shows a linear relation between the magnitude of applied voltage to the magnitude of cantilever displacement.

FIGS. 13A-13C show X-ray and pole figure measurements. FIG. 13A represents the XRD pattern of 50 nm thick layers of Ti deposited at 300K on (100) Si wafers; and (FIG. 13B) represents the XRD pattern of 50 nm thick layers of Ti deposited at 300K on D263 borosilicate glass, demonstrating strong 002 orientation. FIG. 13C shows a pole figure of Ti(002).

FIGS. 14A-14B show XPS measurements. FIG. 14A shows XPS spectra of nitrogen N 1s; FIG. 14B shows XPS spectra of titanium Ti 2p; measurements are for a 50 nm titanium layer, on (100) silicon substrate, exposed to nitrogen plasma at 400K. Times in seconds refer to sputtering times in the XPS chamber as described herein below.

FIG. 15 shows atomic concentration of N, Ti, and Si as function of sputtering time (depth profile) in XPS. Sputtering rate is ˜2.5×10\hat{ }(−11) m/s.

FIGS. 16A-16D illustrates the structural characterization of Si(100)/Ti(50 nm)/Al_{0.75}Sc_{0.25}N(3 μm) films with: an XRD pattern (FIG. 16A); and pole figure (FIG. 16B); of the (002) Bragg-peak, 2 θ=35.55°, FWHM=0.31±0.01°; SEM images of the surface (FIG. 16C) and cross-section (FIG. 16D) of the sample showing pebble-like grains at the surface (mean transverse dimension, 84 nm, as determined by the lineal intercept method) and columnar growth, respectively.

FIGS. 17A-17D illustrate the structural characterization of D263-glass/Ti(50 nm)/Al_{0.75}Sc_{0.25}N(3 μm): XRD pattern (FIG. 17A) and pole figure (FIG. 17B) of the (002) Bragg-peak: 2 θ=35.54°, FWHM=0.23±0.01°; SEM images of the surface (FIG. 17C); and the cross-section (FIG. 17D) showing pebble-like grains at the surface, mean transverse size 101 nm (as determined by the lineal intercept method) and uniform columnar growth, respectively.

FIG. 18 illustrates an XRD pattern of Si(100)/[100 nm Al+50 nm Ti]/Al_{0.75}Sc_{0.25}N(2 μm) sample with the Ti seeding layer and a stress-relieving Al layer.

FIGS. 19A-19D illustrates an SEM image (FIG. 19A) and elemental mapping of a Al_{0.75}Sc_{0.25}N thin film deposited on a Si wafer with Ti seeding layer. Ti FIG. 19B; Sc FIG. 19C; Al FIG. 19D. Electron beam energy during the acquisition was 8 keV.

FIG. 20 illustrates a graph of the pyroelectric current in a Al_{0.75}Sc_{0.25}N sample that is periodically heated with an IR laser; Inset: showing the heating phase of the current decay which was used for fitting to the error function.

FIG. 21 illustrates a schematic of a D263-glass/Ti(50 nm)/Al_{0.75}Sc_{0.25}N(3 μm) sample as prepared for measurements with a 2 mm diameter, black paint-coated upper Ti electrode.

FIGS. 22A-22B show XPS measurements and results. FIG. 22A illustrates the XPS binding energy of nitrogen at temperatures between 233-280K; FIG. 22B shows the maximum intensity of N₂ is electron peak as a function of temperature for Si(100)/Ti(50 nm)/Al_{0.75}Sc_{0.25}N(3 μm) films, heated in ultra-high vacuum from 233K. Shift to lower binding energies upon heating indicates that the sample surface is Al-terminated. Error bars are estimated from instrumental accuracy.

FIG. 23 illustrates quasi-static (0.1 Hz), room temperature, stress vs. electric field dependence for sample (Al,Sc)N sample deposited on a Si wafer between upper and lower Ti electrical contacts.

FIGS. 24A-24D illustrate XRD patterns for samples on thin (<50 nm) TiN films deposited at 573-673K for approximately 20 mins with flowing N₂ plasma: on Si(100) shown in FIG. 24A; and on D263 glass shown in FIG. 24B; Pole figure of Ti(002) is shown in FIG. 24C; and that of TiN(111) is shown in FIG. 24D.

It will be appreciated that for simplicity and clarity of illustration, elements shown in the figures have not necessarily been drawn to scale. For example, the dimensions of some of the elements may be exaggerated relative to other elements for clarity. Furthermore, where considered appropriate, reference numerals may be repeated among the figures to indicate corresponding or analogous elements.

### DETAILED DESCRIPTION OF THE PRESENT INVENTION

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

In some embodiments, provided herein is a process of film deposition of aluminum scandium nitride (AlₓSc₁₋ₓN). In some embodiments, provided herein is a process of film deposition of aluminum nitride. In some embodiments, provided herein is a process of film deposition, comprising deposition of aluminum nitride.

The process and devices described herein include a seeding layer that reacts chemically with (AlSc)N during sputtering (instead of an epitaxial chemically inert layer as known in the art). Using chemically reactive seeding layers has three advantages: a) it greatly simplifies the deposition process, making (AlSc)N available on any substrate withstanding the deposition temperature; b) it significantly reduces Sc-segregation, which allows relatively thick films to be deposited; and c) the (AlSc)N films have low in-plane stress which make them particularly attractive for MEMS applications.

The products prepared by the process described herein comprise highly oriented nanocrystals of (001)-textured (AlSc)N. The oriented (001) grain's columnar growth ensures minimal in-plane stresses, thus minimizing scandium segregation and ensures uniform composition and orientation in prolonged deposition durations. Thus, the resulting (001)-textured films of (AlSc)N can be deposited with any desired thickness, producing the maximum piezoelectric response for any given scandium doping %.

In some embodiments, this invention provides a process for the preparation of AlₓSc₁₋ₓN film, the process comprises:
a) providing a substrate;
b) producing a first layer comprising Ti on said substrate;
c) exposing said first layer to high temperature and nitrogen gas; and
d) producing an upper layer comprising AlₓSc₁₋ₓN.

In one embodiment, this invention provides a process for the preparation of AlₓSc₁₋ₓN film, said process comprising:
a) providing a substrate;
b) producing a first layer comprising Ti on said substrate;
c) producing a TiN layer on said first layer;
d) producing an AlₓSc₁₋ₓN layer on said TiN layer, wherein said AlₓSc₁₋ₓN layer is in contact with said TiN.

In some embodiments, producing an upper layer comprising AlₓSc₁₋ₓN (step (d)) is performed after exposing said first layer to high temperature and nitrogen gas (step (c)). In another embodiment, step (c) is performed before and during step (d). In another embodiment, steps (c) and (d) are performed simultaneously. In some embodiments steps (c) and (d) are performed at least partially in parallel and/or at least partially at the same time and/or simultaneously.

In some embodiments, the process provided herein produces titanium nitride (TiN) when exposing the first layer to high temperature and nitrogen gas (in step (c)), and/or when producing an upper layer comprising AlₓSc₁₋ₓN (in step (d)), or when both steps (c) and (d) are performed.

In another embodiment, the TiN is formed simultaneously with the AlₓSc₁₋ₓN layer. In another embodiment, the TiN is formed as soon as the deposition of AlₓSc₁₋ₓN begins.

In some embodiments, producing a first layer comprising producing Ti in contact with the substrate.

In one embodiment, invention provides a process for the preparation of AlₓSc₁₋ₓN film, the process comprising: (a) providing a substrate; (b) producing a first layer comprising Ti on the substrate, using a Ti target in a sputtering chamber; (c) producing a TiN layer on the first layer, by exposing the Ti layer to nitrogen in a sputtering chamber; (d) producing an AlₓSc₁₋ₓN layer on the TiN layer, by sputtering AlSc from an AlSc target in a sputtering chamber while exposing the sputtering chamber to nitrogen. In one embodiment, such process results in a AlₓSc₁₋ₓN layer which is in contact with a TiN layer.

In some embodiments, the TiN is in the form of a layer. In one embodiment, the TiN is in the form of a homogeneous layer. In one embodiment, the TiN is in the form of a non-homogeneous layer. In one embodiment, the TiN layer is a discontinuous layer. In some embodiments, the TiN is in the form of isolated grains. In some embodiments, the TiN is in a crystal and/or crystalline form. In another embodiment, the TiN crystals are spread un-evenly throughout the surface. In another embodiment, the TiN crystals are spread evenly throughout the surface. In some embodiments TiN is pre-made on a substrate. In some embodiments TiN is pre-made on a substrate upon which other materials are deposited. In some embodiments TiN is sputtered on to the substrate. In some embodiments TiN is formed on a Ti layer by exposing the Ti layer to nitrogen gas. According to this aspect and in one embodiment, nitrogen reacts with Ti to form TiN on the Ti layer. In some embodiments, such process is conducted in a sputtering chamber. In one embodiment, the process of producing TiN on a Ti layer is performed in the presence of nitrogen and optionally other gases such as argon. In one embodiment, the thickness of the TiN layer is 10 nm. In one embodiment, the thickness of the TiN layer ranges between 1 nm and 100 nm. In one embodiment, the thickness of the TiN layer ranges between 1 nm and 20 nm. In one embodiment, the thickness of the TiN layer ranges between 0.5 nm and 5 nm, or between 1 nm and 10 nm, or between 5 nm and 15 nm, or between 7.5 nm and 12.5 nm, or between 9 nm and 11 nm, or between 5 nm and 50 nm.

In one embodiment, the thickness of the Ti layer is 10 nm. In one embodiment, the thickness of the Ti layer ranges between 5 nm and 100 nm. In one embodiment, the thickness of the Ti layer ranges between 10 nm and 20 nm. In one embodiment, the thickness of the Ti layer ranges between 5 nm and 50 nm, or between 10 nm and 100 nm, or between 5 nm and 200 nm, or between 5 nm and 300 nm, or between 10 nm and 275 nm, or between 5 nm and 250 nm.

In some embodiments, the AlₓSc₁₋ₓN layer grow from a TiN seed layer which forms in-situ during deposition.

In some embodiments, the AlₓSc₁₋ₓN layer is manufactured by magnetron reactive sputtering.

In some embodiments, producing a first layer comprising Ti on said substrate, exposing said first layer to high temperature and nitrogen gas; and producing an upper layer comprising AlₓSc₁₋ₓN (steps (b)-(d)) are performed in a sputtering chamber. In another embodiment, producing a first layer comprising Ti on the substrate (step b) is performed by sputtering in a sputtering chamber. In another embodiment, exposing the first layer to high temperature and nitrogen gas (step c) is performed in a sputtering chamber. In another embodiment, producing an upper layer comprising AlₓSc₁₋ₓN (step d) is performed by sputtering in a sputtering chamber.

In one embodiment, sputtering is conducted in a sputtering chamber. In one embodiment sputtering is performed in a sputtering chamber, wherein the sputtering chamber comprising target(s) comprising material(s) to be sputtered. In some embodiment, a sputtering chamber comprises a place to position a sample or a substrate, inlet for gases etc. In some embodiments, a sputtering chamber is designed such that it can be evacuated and in a way that allows the formation of plasma from certain gases in it. A ‘sputtering chamber’ is a term known in the art to describe the chamber in which sputtering is performed.

In some embodiments, the sputtering power density of the scandium/aluminum target is in the range of 0.001 to 20 W/mm². In another embodiment, the sputtering power density is in the range of 0.05 to 10 W/mm². In another embodiment, the sputtering power density is in the range of 0.05 to 5 W/mm². In another embodiment, the sputtering power density is in the range of 0.5 to 5 W/mm². In another embodiment, the sputtering power density is in the range of 1 to 10 W/mm².

In some embodiments, when producing the first layer (step b), the sputtering chamber does not comprise nitrogen gas. In some embodiments, when producing an upper layer comprising AlₓSc₁₋ₓN (step d) the sputtering chamber comprises nitrogen gas.

In some embodiments, a mixture of argon and nitrogen gases of varying Ar/N₂ ratios are used during deposition. In some embodiments, a mixture of argon and nitrogen gases of varying Ar/N₂ ratios are used as a sputtering and reactive gas respectively.

In another embodiment, the percentage of the nitrogen in the mixture of argon and nitrogen gases is between 20%-100%. In some embodiments, step d (producing an upper layer comprising AlₓSc₁₋ₓN) is done by sputtering using 80% nitrogen and 20% argon in the atmosphere.

In some embodiments, the sputtering chamber pressure, of step (c) and/or step (d) is in the range of 1-60 mTorr. In another embodiment, the sputtering chamber pressure is in the range of 1-5 mTorr. In another embodiment, the sputtering chamber pressure is in the range of 5-10 mTorr. In another embodiment, the sputtering chamber pressure is in the range of 1-10 mTorr. In another embodiment, the sputtering chamber pressure is in the range of 10-20 mTorr. In another embodiment, the sputtering chamber pressure is in the range of 20-60 mTorr. In another embodiment, the sputtering chamber pressure is 5 mTorr.

In some embodiments, the duration of step (c), exposing said first layer to high temperature and nitrogen gas, is in the range of 10 min to 2 hours. In another embodiment, the duration of step © is about 1 hour.

In one embodiment, the term “a” or “one” or “an” refers to at least one. In one embodiment the phrase “two or more” may be of any denomination, which will suit a particular purpose. In one embodiment, “about” or “approximately” may comprise a deviance from the indicated term of +1%, or in some embodiments, −1%, or in some embodiments, ±2.5%, or in some embodiments, ±5%, or in some embodiments, ±7.5%, or in some embodiments, ±10%, or in some embodiments, ±15%, or in some embodiments, ±20%, or in some embodiments, ±25%.

In some embodiments, x of AlₓSc₁₋ₓN of this invention, ranges between 0.50≤x≤1. In some embodiments, x of AlₓSc₁₋ₓN of this invention, ranges between 0.57≤x≤1. In some embodiments, x of AlₓSc₁₋ₓN, ranges between 0.57≤x≤0.8. In some embodiments, x of AlₓSc₁₋ₓN, ranges between 0.7≤x≤0.8. In another embodiment, AlₓSc₁₋ₓN is Al_{0.50}Sc_{0.20}N. In one embodiment, AlₓSc₁₋ₓN is Al_{0.75}Sc_{0.25}N. In another embodiment, AlₓSc₁₋ₓN is Al_{0.7}Sc_{0.30}N. In another embodiment, the AlₓSc₁₋ₓN is AlN, when x is 1.

In some embodiments, the process of this invention can be carried out using any substrate. In one embodiment, the substrate comprises an inorganic and/or an organic material. In one embodiment, the substrate comprises an inorganic material. In one embodiment, the substrate comprises an organic material. In one embodiment, the substrate comprises a polymer. In one embodiment, the substrate comprises silicon oxide. In one embodiment, the substrate comprises glass. In one embodiment, the substrate comprises borosilicate glass. In one embodiment, the substrate comprises silicon. In one embodiment, the substrate comprises a metal. In another embodiment, the substrate comprises a non-metal. In one embodiment, the substrate comprising a material selected from tin oxide, indium tin oxide and aluminum oxide. In one embodiment, the substrate comprises a material selected from a single crystal, a polycrystalline, an amorphous material or any combination thereof. In one embodiment, the substrate comprises wood. In some embodiments, the substrate comprises a combination of any of the materials described herein above.

In some embodiments, the substrate is (100) Si. In one embodiment, the Si is 250±25 μm thick. In some embodiments the substrate comprises (111) Si. In some embodiments the substrate comprises n-doped Si wafers whereas in other embodiments the substrate comprises p-doped Si wafers. In some embodiments a native oxide (SiO₂) is present on the Si substrate. In other embodiments there is no oxide. In other embodiments the silicon oxide is grown chemically and in other embodiments it is grown thermally. In some embodiments the SiO₂ forms a continuous layer on the Si substrate and in other embodiments the SiO₂ is discontinuous. In some embodiments the silicon oxide is amorphous and in other embodiments it is any crystalline polymorph. In some embodiments, the substrate is D263 borosilicate (Schott) glass. In another embodiment, the borosilicate is 500±50 μm thick.

In some embodiments the substrate is any combination of layers upon which other layers are deposited. For example, in one embodiment, the substrate refers to any layers that are present below the Ti layer which is the first layer. In some embodiment, any preliminary layer or layers can form the substrate onto which a Ti layer is applied. For example and in one embodiment, the substrate comprises a layer of one material coated by a layer of a different material.

In some embodiments, prior to step (b) and/or prior to step (d) of the process provided herein, the substrate is cleaned. In some embodiment, the cleaning of the substrate comprises: a) washing with an organic or inorganic solvent; and/or, b) washing with organic or inorganic acid; and/or, c) treating with gas plasma; and/or, d) cleaning with ultraviolet ozone cleaning systems (e.g., UVOCS).

In one embodiment, the cleaning of the substrate step is performed prior to the deposition of the Ti and is performed with nitric Acid, sulfuric acid, hydrogen peroxide, water, hydrofluoric acid, piranha solution or any combination thereof and/or any sequence thereof. In one embodiment, the cleaning step is performed prior to the deposition of the Ti and is conducted by solvents with increasing polarity. In another embodiment, the solvents with increasing polarity are selected from, but not limited to, acetone, ethanol, ethyl acetate, isopropyl alcohol (IPA), DDI (distilled de-ionized water), or combination thereof. In some embodiments, further cleaning includes: nitric acid/sulfuric acid/hydrogen peroxide/water/hydrofluoric Acid or any combination thereof and/or in any sequence thereof.

In one embodiment, the cleaning step is performed prior to the deposition of the Ti and is conducted with an acid in order to remove a native oxide layer and/or surface contaminants. In one embodiment, the cleaning step is performed prior to the deposition of the Ti and is conducted with diluted hydrofluoric acid in order to remove a native oxide layer and/or surface contaminants. In one embodiment, the cleaning step is performed prior to the deposition of the Ti (prior to sputtering) and the cleaning step comprises argon plasma treatment to remove organic contaminants. In one embodiment, the cleaning step comprises oxygen and argon plasma treatment to remove organic contaminants.

In some embodiment, the cleaning of the substrate comprises: a) washing with an organic or inorganic solvent, or; b) washing with organic or inorganic acid; or c) treating with gas plasma; d) or any combination thereof.

In one embodiment, the cleaning step is performed prior to the deposition of the Ti and is conducted under gas atmosphere at 1-15 mTorr chamber pressure. In one embodiment the samples undergo wet cleaning processes before sputtering onto the samples. Such wet clean can comprise cleaning with solvents, hydrofluoric acid (HF) and other solvents/acids detailed above.

In one embodiment, the cleaning step is performed prior to the deposition of Ti and is conducted under gas flow of 1-30 sccm. In one embodiment, the sample is cleaned in the deposition chamber with plasma under a flow of argon and oxygen; typically, at about 50:50 argon to oxygen. In one embodiment, dry cleaning of the sample, takes place within the sputtering chamber.

In one embodiment, the sample, at any stage, can be cleaned with sonication. In one embodiment the sample is sonicated in any of the liquids described herein, or a combination thereof.

In one embodiment, the deposition of Ti (production of the first layer—step (b)) is performed in a chamber pressure of 1-15 mTorr and gas flow of 10-40 sccm. In some embodiments, the sputtering power used during deposition processes of steps (b) and (d) is between 50-350 Watt.

In one embodiment, the production of AlₓSc₁₋ₓN layer is done by deposition from an AlₓSc₁₋ₓ (wherein 0.57≤x≤1) target in the presence of N₂ gas. In one embodiment, the deposition is done from a single metallic alloyed target. In one embodiment, the deposition is done from a single metallic alloyed target comprising 25% scandium 75% aluminum. In another embodiment, the deposition is done from a single metallic alloyed target comprising 30% scandium 70% aluminum. In one embodiment, the deposition is done from a single metallic alloyed target comprising 25%-30% scandium and 70%-75% aluminum. In one embodiment, the deposition is done from a single metallic alloyed target comprising 20%-30% scandium and 70%-80% aluminum. In one embodiment, the deposition is done from a single metallic alloyed target comprising 15%-35% scandium and 65%-85% aluminum.

In one embodiment, the deposition of AlSc in the presence of N₂ gas is carried out under the following conditions:
a) chamber pressure set to 1-10 mT, and
b) gas flow 1-30 sccm.

In one embodiment, the gas flow comprises 10 sccm Argon and 25 sccm Nitrogen flow. In one embodiment, the deposition height, the height between the target and the sample, is ranging between 20-30 cm.

In some embodiments, producing a first layer comprising Ti on said substrate (step b) is conducted at room temperature.

In some embodiments, the Ti film (layer) of step (b) includes a subsequent step (step c), wherein step (c) comprises high temperature and nitrogen plasma in the sputtering chamber. In another embodiment, the high temperature of step c is between 150-500° C. In another embodiment the high temperature is about 400° C. In another embodiment, the high temperature of step (c) is between 150-300° C. In another embodiment step (c) is carried out at a temperature ranging between 25° C. to 500° C.

In some embodiments, step (d) is conducted at an elevated temperature. In another embodiment, the elevated temperature is a temperature ranging between room temperature and 500° C. In another embodiment, the elevated temperature is a temperature ranging between 250° C. and 600° C. In another embodiment, elevated temperature is a temperature between 150° C.-400° C. In another embodiment, elevated temperature is a temperature between 150° C.-300° C. In another embodiment, the elevated temperature is between 300° C.-500° C. In another embodiment, the elevated temperature is between 250° C.-500° C. In another embodiment, the elevated temperature is between 200° C.-400° C. In another embodiment, the elevated temperature is between 150° C.-400° C. In another embodiment, the elevated temperature is between 150° C.-350° C. In another embodiment, the elevated temperature is between 200° C.-400° C. In another embodiment step (d) is conducted at a temperature ranging between 250° C.-600° C.

In some embodiments, the temperature is held at a specific value for the full duration of one or more of the individual steps of the process. In another embodiment, the temperature is varied during one or more of the individual steps. In one embodiment, the temperature at which a step is carried out begins at a low temperature and finishes at a high temperature. In another embodiment the temperature at which a step is carried out begins at a high temperature and finishes at a lower temperature. In another embodiment, the temperature is ramped up to a specific value over a period of time. In another embodiment, temperature ramping occurs for at least part of the duration of a step in at least one step in the process of deposition. In another embodiment, the temperature can be ramped up and in another embodiment the temperature can be ramped down. In further embodiments, the rate of temperature ramping can be different at each step of the process.

In some embodiments, exposing the first layer to high temperature and nitrogen gas at step (c), causes a reaction which forms TiN, which is the actual seeds for step (d).

In some embodiment, an aluminum scandium nitride film is sputter-deposited at a substrate temperature of 200° C.-400° C. or of 250° C.-600° C. The deposition is conducted on the Ti seed layers in step d.

In some embodiments provided herein is a process which utilizes a layer of titanium (Ti) (said first layer) deposited upon the substrate, acting as the reactive-seeding layer.

In one embodiment, upon exposure to a nitrogen rich environment at high temperature, an interaction layer of titanium nitride (TiN) is formed with (111) favorable growth orientation. An epitaxial match, with a 2:1 face ratio exists between the equilateral triangles (111) TiN plane and the hexagonally structured (001) (AlSc)N which ensures prolonged oriented grain growth.

In some embodiments, the process provided herein, further comprises producing a top layer comprising an electrically conductive material on said upper layer (following step d). In one embodiment, the electrically conductive material is selected from Cu, Ag, Au, Pt, Pd, Ni, Al, Ta and Ti or combination thereof. In one embodiment, the top layer comprises Ti. In one embodiment, the electrically conductive material is selected from conductive copper tape, carbon black, graphene-based tape, carbon nanotube tape or any other conductive tape and/or paste is used to connect the top electrode. In other embodiments, the production and/or deposition of any of the layers is carried out via sputtering, electron-beam deposition, thermal deposition, atomic layer deposition, chemical/physical vapor deposition, wet process and/or any combination thereof.

In another embodiment, the thickness of the electrically conductive material as a top layer is between 20-500 nm. In another embodiment, the Ti top layer is a 20-200 nm thick electrode. In another embodiment, the Ti top layer is a 50-300 nm thick electrode. In another embodiment, the Ti top layer is a 50-150 nm thick electrode. In another embodiment, the Ti top layer is a 150-250 nm thick electrode. In another embodiment, the Ti top layer is a 250-400 nm thick electrode. In another embodiment, the Ti top layer is a 200-500 nm thick electrode. In another embodiment, the Ti top layer is a 250-400 nm thick electrode. In another embodiment, the thickness of the Ti top layer is higher than 50 nm. In one embodiment the electrically conductive electrode material is deposited onto the sample via electron-beam evaporation and/or by thermal evaporation and/or by sputtering.

In another embodiment, after the deposition of Ti, TiN, and AlₓSc₁₋ₓN layers, a top titanium electrode is applied. In another embodiment, the top titanium electrode is about 100 nm thick. In another embodiment, the top titanium electrode is about 50-150 nm thick.

In some embodiments, the first layer and top layer provided herein are used as electrodes. In one embodiment, the electrodes are independently connected to a power supply.

In some embodiments, a TiN layer is made by a process of this invention. In some embodiments, the process provided herein, provides combined Ti and TiN layer (Ti/TiN). In some embodiments, the thickness of the combined Ti and TiN layer (Ti/TiN) is between 50-300 nm. In some embodiments, the thickness of the combined Ti and TiN layer (Ti/TiN) is between 20-300 nm, or between 20 nm and 100 nm, or between 10 nm and 200 nm.

In some embodiments, the Ti/TiN layer provided herein functions as a bottom electrode on the substrate and/or as a stress-relieving layer and/or as a seed layer. In one embodiment, the Ti/TiN layer functions as a bottom electrode on the substrate. In one embodiment, the Ti/TiN layer functions as a stress-relieving layer. In one embodiment, the Ti/TiN layer functions as a seed layer.

In some embodiments, an AlₓSc₁₋ₓN layer is produced by the process provided herein. In some embodiments, an AlₓSc₁₋ₓN film is produced by the process provided herein. In some embodiments, an AlₓSc₁₋ₓN thin film is produced by the process provided herein.

In some embodiments, the internal stress of the AlₓSc₁₋ₓN layer is in the range of 60-300 MPa.

In some embodiments, the thickness of the AlₓSc₁₋ₓN layer is in the range of 0.1 μm-10 μm. In some embodiments, the thickness of the AlₓSc₁₋ₓN layer is in the range of 0.1 μm to 5 μm. In some embodiments, the AlₓSc₁₋ₓN layer is textured with the c-axis (001), normal to the substrate. In some embodiments, the AlₓSc₁₋ₓN layer is textured with the c-axis (002), normal to the substrate.

In some embodiments, provided herein is a polycrystalline AlₓSc₁₋ₓN film wherein:
a) the orientation of the film is 001/002;
b) the thickness of the film ranges between 100 nm and 5 μm;
c) the piezoelectric coefficient of said film ranges between 1.0 C/m² and 4.0 C/m²;
d) the compressive stress of said film ranges between 5 MPa and 500 MPa
e) or a combination thereof.

In some embodiments, provided herein is a polycrystalline AlₓSc₁₋ₓN film wherein:
a) the orientation of said film is 001/002;
b) the piezoelectric coefficient of said film ranges between 1.0 C/m² and 4.0 C/m²;
c) the compressive stress of said film ranges between 5 MPa and 500 MPa
d) or a combination thereof.

In another embodiment, the orientation of AlₓSc₁₋ₓN is 001/002. In another embodiment, the thickness of the polycrystalline AlₓSc₁₋ₓN film ranges between 100 nm and 5 μm. In another embodiment, the piezoelectric coefficient of the polycrystalline AlₓSc₁₋ₓN film ranges between 1.0 C/m² and 4.0 C/m². In another embodiment, the compressive stress of the polycrystalline AlₓSc₁₋ₓN film ranges between 5 MPa and 500 MPa.

In one embodiment, this invention provides an AlₓSc₁₋ₓN layer made by the process as described herein above.

In one embodiment, for the AlₓSc₁₋ₓN layer:
the internal stress is in the range of 60-300 MPa; or wherein
the layer has c-axis (001) normal to the substrate; or
a combination thereof.

In one embodiment, this invention provides a polycrystalline AlₓSc₁₋ₓN film wherein:
the orientation of said film is 001/002; or
the piezoelectric coefficient of said film ranges between 1.0 C/m² and 4.0 C/m²; or
the compressive stress of said film ranges between 5 MPa and 500 MPa; or
any combination thereof.

In one embodiment, the thickness of the polycrystalline AlₓSc₁₋ₓN film is greater than 0.8 μm.

In one embodiment, the thickness of the polycrystalline AlₓSc₁₋ₓN film ranges between 0.8 μm and 10 μm or between 0.5 μm and 4 μm.

In some embodiments, the term “layer” disclosed herein is used interchangeably with the term “film”. In some embodiments, “(AlSc)N” disclosed herein is used interchangeably with “AlₓSc₁₋ₓN”. In some embodiments, “(AlSc)N” disclosed herein is used interchangeably with “AlₓSc₁₋ₓN” wherein x is 0.57≤x≤1 or wherein x=1. In some embodiments, “(AlSc)N” disclosed herein is used interchangeably with AlScN.

In one embodiment, this invention provides a layered material comprising:
a substrate;
a Ti layer;
a TiN layer;
an AlₓSc₁₋ₓN layer.

In one embodiment, in layered materials of this invention, the Ti layer is in contact with the substrate, the TiN layer is in contact with the Ti layer and the AlₓSc₁₋ₓN layer is in contact with the TiN layer.

In one embodiment, this invention provides a layered material consisting of:
a substrate;
a Ti layer;
a TiN layer;
an AlₓSc₁₋ₓN layer.

In one embodiment, in layered materials of this invention, the Ti layer is in contact with the substrate, the TiN layer is in contact with the Ti layer, the AlₓSc₁₋ₓN layer is in contact with the TiN layer.

In one embodiment, this invention provides a layered material comprising:
a Ti layer;
a TiN layer;
an AlₓSc₁₋ₓN layer.

In one embodiment, in layered materials of this invention, the TiN layer is in contact with the Ti layer and the AlₓSc₁₋ₓN layer is in contact with the TiN layer.

In one embodiment, this invention provides a layered material consisting of:
a Ti layer;
a TiN layer;
an AlₓSc₁₋ₓN layer.

In one embodiment, in layered materials of this invention, the TiN layer is in contact with the Ti layer and the AlₓSc₁₋ₓN layer is in contact with the TiN layer.

In some embodiments, the polycrystalline AlₓSc₁₋ₓN film is (001) oriented with pole-figure width <2°. In another embodiment, the polycrystalline Al_{0.75}Sc_{0.25}N film is (001) oriented with pole-figure width <2°.

In some embodiments, provided herein is a piezoelectric device comprising:
a) a substrate;
b) a first layer comprising Ti on said substrate;
c) an upper layer comprising AlₓSc₁₋ₓN; and
d) a top layer comprising an electrically conductive material on said upper layer.

In one embodiment, the piezoelectric device further comprises TiN on said first layer.

In some embodiments, provided herein is a piezoelectric device comprising:
a) a substrate;
b) a first layer comprising Ti on said substrate,
c) optionally TiN on the first layer;
d) an upper layer comprising AlₓSc₁₋ₓN; and
e) a top layer comprising an electrically conductive material on said upper layer.

In some embodiments, provided herein is a piezoelectric device comprising:
a) a substrate;
b) a first layer comprising Ti on said substrate,
c) TiN on the first layer;
d) an upper layer comprising AlₓSc₁₋ₓN; and
e) a top layer comprising an electrically conductive material on said upper layer.

In one embodiment, the electrically conductive material of the piezoelectric device is selected from Cu, Ag, Au, Pt, Pd, Ni, Al, Ta and Ti or a combination thereof.

In one embodiment, the piezoelectric device is operable under electric fields of up to 100 Vpp. Peak to peak voltage (Vpp) is typically defined as a parameter measured between the maximum signal amplitude value and its minimum value (which can be negative) over a single period.

In some embodiments, provided herein is a cantilever comprising a polycrystalline AlₓSc₁₋ₓN film, wherein the polycrystalline AlₓSc₁₋ₓN film comprises:
a. the orientation of said film is 001/002;
b. the thickness of said film ranges between 100 nm and 5 μm;
c. the piezoelectric coefficient of said film ranges between 1.0 C/m² and 4.0 C/m²;
d. the compressive stress of said film ranges between 5 MPa and 500 MPa
e. or a combination thereof.

In some embodiments, provided herein is a cantilever comprising a piezoelectric device, wherein the piezoelectric device comprises:
a. a substrate;
b. a first layer comprising Ti on said substrate,
c. an upper layer comprising AlₓSc₁₋ₓN; and
d. a top layer comprising an electrically conductive material on said upper layer.

In another embodiment, the cantilever comprising a piezoelectric device, wherein the piezoelectric device further comprises TiN on said first layer. According to this aspect and in one embodiment, provided herein is a cantilever comprising a piezoelectric device, wherein the piezoelectric device comprises:
e. a substrate;
f. a first layer comprising Ti on said substrate;
g. a TiN layer in contact with the Ti of the first layer;
h. an upper layer comprising AlₓSc₁₋ₓN; and
i. a top layer comprising an electrically conductive material on said upper layer.

In some embodiments, provided herein is a cantilever comprising a piezoelectric device, wherein the piezoelectric device comprises:
a. a substrate;
b. a first layer comprising Ti on said substrate,
c. optionally TiN on the first layer;
d. an upper layer comprising AlₓSc₁₋ₓN; and
e. a top layer comprising an electrically conductive material on said upper layer.

In some embodiments, provided herein is a micro electro-mechanical system (MEMS) comprising a polycrystalline AlₓSc₁₋ₓN film, wherein the polycrystalline AlₓSc₁₋ₓN film comprises:
a. the orientation of said film is 001/002;
b. the piezoelectric coefficient of said film ranges between 1.0 C/m² and 4.0 C/m²;
c. the compressive stress of said film ranges between 5 MPa and 500 MPa
d. or a combination thereof.

In some embodiments, provided herein is a micro electro-mechanical system (MEMS) comprising a piezoelectric device, wherein the piezoelectric device comprises:
a. a substrate;
b. a first layer comprising Ti on said substrate;
c. an upper layer comprising AlₓSc₁₋ₓN; and
d. a top layer comprising an electrically conductive material on said upper layer.

In another embodiment, the MEMS comprising a piezoelectric device, wherein the piezoelectric device further comprises TiN on said first layer.

In some embodiments, provided herein is a micro electro-mechanical system (MEMS) comprising a piezoelectric device, wherein the piezoelectric device comprises:
e. a substrate;
f. a first layer comprising Ti on said substrate;
g. optionally TiN on the first layer;
h. an upper layer comprising AlₓSc₁₋ₓN; and
i. a top layer comprising an electrically conductive material on said upper layer.

In some embodiments, the process of this invention is suited for industrial, large scale and/or semiconductor manufacturing.

In some embodiments, the titanium nitride produced in the process provided herein has a rock-salt structure with a (111) preferred growth orientation.

In some embodiments, the process of this invention utilizes a single alloyed AlₓSc₁₋ₓ target. In some embodiments, the process of this invention utilizes a single alloyed AlₓSc₁₋ₓ target with Sc % varying between 0%-50%. Sputtering power density of the scandium/aluminum target is in the range of 0.001 to 20 W/mm² in some embodiments. In one embodiment, the sputtering power density is in the range of 0.05 to 10 W/mm².

In some embodiments, provided herein is a mixture of argon and nitrogen gases for use in varying ratios during the deposition. In some embodiments, provided herein is a mixture of argon and nitrogen gases for use in varying ratios during the deposition as a sputtering and reactive gas, with chamber pressures of several mTorr.

In some embodiments, the process provided herein utilizes a layer of titanium (Ti) deposited upon the substrate, acting as the reactive-seeding layer. In one embodiment, the deposition of a layer of titanium (Ti) upon the substrate provides a reactive-seeding layer. In one embodiment, the titanium (Ti) layer on the substrate acts as a reactive-seeding layer.

In some embodiments, upon exposure to a nitrogen rich environment at high temperatures an interaction layer of titanium nitride (TiN) forms a (111) favorable growth orientation. In some embodiments, provided herein an epitaxial match, with a 2:1 face ratio exists between the equilateral triangles (111) TiN plane and the hexagonally structured (001) (AlSc)N which ensures prolonged oriented grain growth.

In some embodiments, the process of this invention utilizes various substrate temperatures throughout the deposition in ranges between room temperature (RT) to 500° C. In one embodiment, the substrate temperature throughout the deposition is between RT to 100° C. In another embodiment, the substrate temperature throughout the deposition is between RT to 200° C. In another embodiment, the substrate temperature throughout the deposition is between RT to 300° C. In another embodiment, the substrate temperature throughout the deposition is between 250° C. to 400° C. In another embodiment, the substrate temperature throughout the deposition is between 200° C. to 400° C. or between room temperature and 600° C. In some embodiments, the TiN layer is formed under a temperature gradient. In another embodiment the temperature gradient is between 200° C. to 400° C.

In some embodiments, the Ti layer is treated by an oxidizing gas and/or an inert gas or any combination thereof. In some embodiments, the Ti/TiN layer is treated by an oxidizing gas and/or an inert gas or any combination thereof. In one embodiment, the Ti or Ti/TiN layer is treated by an oxidizing gas. In another embodiment, the oxidizing gas is selected from oxygen, nitrogen, water, or any combination thereof. In one embodiment, the Ti or Ti/TiN layer is treated by an inert gas. In another embodiment, the inert gas is selected from argon, helium, neon, nitrogen or any combination thereof.

In some embodiments, the deposited aluminum scandium nitride piezoelectric layer is textured with the c-axis (001), normal to the substrate. In some embodiments, the deposited aluminum scandium nitride piezoelectric layer is highly textured with the c-axis (001), normal to the substrate. In some embodiments, the thickness of the Ti or Ti/TiN layer provided herein is between 50-300 nm. In some embodiments, the Ti layer undergoes a reaction with nitrogen. In some embodiments, the TiN layer causes surface smoothing. In some embodiments, the Ti/TiN reaction layer, which results in surface-smoothening, acts as an in-situ seed layer for (AlSc)N layer. In some embodiments, the internal stresses of the deposited aluminum scandium nitride piezoelectric layer are in the range of 60-300 MPa.

In some embodiments, the thickness of the deposited aluminum scandium nitride piezoelectric layer is between 0.1-10 μm. In some embodiments, the thickness of the deposited aluminum scandium nitride piezoelectric layer is between 0.1-5 μm. In some embodiments, the thickness of the deposited aluminum scandium nitride piezoelectric layer is between 0.75-5 μm, or between 0.8-5 μm, or between 0.8-10 μm, or between 0.8-20 μm, or between 1.0 and 20 μm, or between 0.8 and 50 μm. In some embodiments, the thickness of the deposited aluminum scandium nitride piezoelectric layer is higher than 0.8 μm. In some embodiments, the thickness of the deposited aluminum scandium nitride piezoelectric layer is higher than 0.75 m, or higher than 0.8 m, or higher than 1.0 μm. In one embodiment, the thickness of the deposited aluminum scandium nitride piezoelectric layer is lower than 0.75 m or lower than 0.70 km.

In one embodiment, description of figures/results that refer to results for (AlSc)N films deposited on Ti seed layers, refers to AlScN layers produced by processes of this invention. According to this aspect and in one embodiment, such description refers to samples wherein a TiN layer is present between the Ti layer and the AlScN layer. However, for simplicity, the TiN layer is not described/recited in embodiments of this invention. In some embodiment, the TiN layer is present between the Ti layer and the AlScN layer, but is not mentioned for simplicity of description.

In some embodiments, the deposited aluminum scandium nitride piezoelectric layer is of uniform, homogenous chemical composition.

In one embodiment, the AlScN layer is in contact with the TiN layer. In one embodiment, there is no other material present between the TiN and the AlScN layer. In one embodiment, the layers formed by processes of this invention do not comprise Cu (copper). In one embodiment, the layers formed in processes of this invention do not comprise AlCu.

In one embodiment, there is no AlCu or AlCuN layer deposited on top of the TiN layer in processes of this invention. In one embodiment, there is no AlCu or AlCuN layer deposited beneath the AlScN layer in processes of this invention. In one embodiment, there is no AlCu or AlCuN layer present between the TiN layer and the AlScN layer in processes and in devices/systems of this invention.

In one embodiment, in layered materials of this invention comprising Ti/TiN/AlScN layers as described herein above, there is no other material present between the TiN and the AlScN layers. In one embodiment, layered materials of this invention do not comprise Cu (copper). In one embodiment, layered materials of this invention do not comprise AlCu. In one embodiment, there is no AlCu or AlCuN layer present between the TiN layer and the AlScN layer in piezoelectric material/devices/systems/cantilevers/films of this invention.

In one embodiment, there is no Cu present between the TiN layer and the AlScN layer in devices/systems/cantilevers of this invention. In one embodiment, there is no Cu layer present between the TiN layer and the AlScN layer in devices/systems/cantilevers of this invention. In one embodiment, there is no layer that comprises copper which is present between the TiN layer and the AlScN layer in devices/systems/cantilevers of this invention.

In one embodiment, as described herein above, the production of AlₓSc₁₋ₓN layer is done by deposition from an AlₓSc₁₋ₓ (wherein 0.57≤x≤1) target in the presence of N₂ gas. In one embodiment, the deposition is done from a single metallic alloyed target. In one embodiment, the deposition is done from a single metallic alloyed target comprising 13%-30% scandium and 70%-87% aluminum. In one embodiment, the deposition is done from a single metallic alloyed target comprising 15%-30% scandium and 70%-85% aluminum. In one embodiment, the deposition is done from a single metallic alloyed target comprising 15%-35% scandium and 65%-85% aluminum.

In some embodiments, this invention provides AlₓSc₁₋ₓN films with:
a) (001)/(002) orientation; and
b) low stress.

In one embodiment, low stress is a stress below 100 MPa, σ<100 MPa.

In one embodiment, piezoelectric performance or piezoelectric response of materials, films, device and layers of this invention is evaluated by the piezoelectric coefficient.

In one embodiment, when producing the first layer (step (b)), the sputtering chamber does not comprise nitrogen gas.

In one embodiment, when producing the TiN layer and the AlₓSc₁₋ₓN layer (steps (c) and (d)) the sputtering chamber comprises nitrogen gas.

In one embodiment, the thickness of the films is higher than 1 μm.

In one embodiment, this invention provides a process for the preparation of AlₓSc₁₋ₓN film, said process comprising:
e) providing a substrate;
f) producing a first layer comprising Ti on said substrate;
g) producing a TiN layer on said first layer;
h) producing an AlₓSc₁₋ₓN layer on said TiN layer, wherein said AlₓSc₁₋ₓN layer is in contact with said TiN.

In one embodiment, steps (b)-(d) are performed in a sputtering chamber. In one embodiment, step (b) is conducted by sputtering Ti. In one embodiment, step (c) comprises exposing the first layer to nitrogen gas, thus forming a TiN layer. In one embodiment, step (d) of producing said AlₓSc₁₋ₓN layer comprises sputtering AlₓSc₁₋ₓ on said TiN layer in the presence of nitrogen gas. In one embodiment, step (d) is performed after step (c) or wherein steps (c) and (d) are performed simultaneously or wherein steps (c) and (d) are performed at least partially at the same time.

In one embodiment, step (c) comprises exposing said first layer to a temperature ranging between 25° C. and 600° C. and to nitrogen gas.

In one embodiment, when producing the first layer (step (b)), the sputtering chamber does not comprise nitrogen gas.

In one embodiment, when producing the TiN layer and the AlₓSc₁₋ₓN layer (steps (c) and (d)) the sputtering chamber comprises nitrogen gas.

In one embodiment, x in AlₓSc₁₋ₓN ranges between 0.57≤x≤1.

In one embodiment, AlₓSc₁₋ₓN is Al_{0.50}Sc_{0.20}N or Al_{0.75}Sc_{0.25}N or Al_{0.7}Sc_{0.3}N. In one embodiment, the thickness of said AlₓSc₁₋ₓN layer is greater than 0.8 μm. In one embodiment, prior to step (b), said substrate is cleaned. In one embodiment, the cleaning comprises the use of:
organic or inorganic solvent; and/or
organic or inorganic acid; and/or
gas plasma.

In one embodiment:
step (b) is conducted at room temperature;
step (c) is conducted at a temperature ranging between 25° C. to 400° C.; and
step (d) is conducted at a temperature ranging between 250° C. to 600° C.

In one embodiment:
step (b) is conducted under argon;
step (c) is conducted under a gas comprising nitrogen and argon; and
step (d) is conducted under a gas comprising nitrogen and argon.

In one embodiment, step (b), step (c), step (d) or any combination thereof is conducted at a pressure lower than 1 atm.

In one embodiment, the process further comprising producing a top layer comprising an electrically conductive material on said AlₓSc₁₋ₓN layer. In one embodiment, the electrically conductive material is selected from Cu, Ag, Au, Pt, Pd, Ni, Al, Ta and Ti or a combination thereof. In one embodiment, the top layer comprises Ti. In one embodiment, the first layer and the top layer are used as electrodes. In one embodiment, the electrodes are independently connected to a power supply.

In one embodiment, the thickness of the combined Ti layer and TiN layer is between 50-300 nm.

In one embodiment, this invention provides a Ti/TiN layer made by the process as described herein above, wherein the thickness of the Ti/TiN layer is ranging between 50-300 nm. In one embodiment, this invention provides an AlₓSc₁₋ₓN layer made by the process as described herein above.

In one embodiment, for the AlₓSc₁₋ₓN layer:
the internal stress is in the range of 60-300 MPa; or
the layer has c-axis (001) normal to the substrate; or
a combination thereof.

In one embodiment, this invention provides a polycrystalline AlₓSc₁₋ₓN film wherein:
the orientation of said film is 001/002; or
the piezoelectric coefficient of said film ranges between 1.0 C/m² and 4.0 C/m²; or
the compressive stress of said film ranges between 5 MPa and 500 MPa; or
any combination thereof.

In one embodiment, the thickness of the polycrystalline AlₓSc₁₋ₓN film is greater than 0.8 μm.

In one embodiment, the thickness of the AlₓSc₁₋ₓN film ranges between 0.8 μm and 10 μm or between 0.5 μm and 4 μm.

In one embodiment, this invention provides a piezoelectric device comprising:
a substrate;
a first layer comprising Ti on said substrate;
TiN in contact with said Ti layer;
a layer comprising AlₓSc₁₋ₓN in contact with said TiN; and
a top layer comprising an electrically conductive material on said AlₓSc₁₋ₓN layer.

In one embodiment, the electrically conductive material is selected from Cu, Ag, Au, Pt, Pd, Ni, Al, Ta and Ti or a combination thereof.

In one embodiment, the piezoelectric device is operable under electric fields of up to 100 Vpp.

In one embodiment, this invention provides a cantilever comprising a AlₓSc₁₋ₓN layer as described herein above. In one embodiment, this invention provides a cantilever comprising a piezoelectric device as described herein above.

In one embodiment, this invention provides a micro electro-mechanical system (MEMS) comprising an AlₓSc₁₋ₓN layer as described herein above. In one embodiment, this invention provides a micro electro-mechanical system (MEMS) comprising a piezoelectric device as described herein above.

In one embodiment, this invention provides a process for the preparation of AlₓSc₁₋ₓN film, said process comprising:
e. providing a substrate;
f. producing a first layer comprising Ti on said substrate;
g. exposing said first layer to high temperature and nitrogen gas; and
h. producing an upper layer comprising AlₓSc₁₋ₓN.

In one embodiment, this invention provides a piezoelectric device comprising:
e. a substrate;
f. a first layer comprising Ti on said substrate;
g. an upper layer comprising AlₓSc₁₋ₓN; and
h. a top layer comprising an electrically-conductive material on said upper layer.

In one aspect, the piezoelectric device further comprising TiN on said first layer.

In one embodiment, sputtering times can be modified to achieve layers with different thicknesses. Examples are described herein. Other sputtering times can be used as needed.

The present invention allows to obtain such properties of (001)/(002) orientation and low stress for film thicknesses exceeding 1 μm in some embodiments.

### EXAMPLES

### Example 1

### Sample Preparation: Titanium Seed Layers

Titanium films ˜50 nm thick were sputter deposited at a 25° C. substrate temperature on <100>2″ Intrinsic\P-Type silicon wafers and D263 borosilicate glass [Ti-1-4, Table.1]. Cleaning of the wafers prior to deposition was conducted by solvents with increasing polarity (Acetone, IPA, DDI). Diluted hydrofluoric acid was used in order to remove the native oxide layer and surface contaminants prior to depositions. Prior to sputtering, the substrates underwent argon and oxygen plasma cleaning to remove organic contaminants at 10 mTorr chamber pressure with argon and oxygen flow of 10 sccm. The films were deposited from a 2″ 5N Ti single target, using DC magnetron sputtering (ATC Orion Series Sputtering Systems, AJA international Inc) at 150 Watt. Deposition height was 24 cm, chamber pressure of 5 mTorr and argon flow of 30 sccm. One set of depositions [Ti, 3-4, Table.1] included a subsequent step. A soak at 400° C. in a 5 mTorr Nitrogen environment with gas flow of 30 sccm for 1 hour duration.

In another embodiment of this example all gasses used were of 6N purity and were supplied by Gas Technologies Israel. HF (hydrofluoric acid), organic solvents, acetone and isopropyl alcohol (IPA), of semiconductor grade (CMOS, Sigma Aldrich), were used for cleaning substrates. Furthermore, 50 nm thick titanium films were deposited by sputtering, keeping the substrate at room temperature. Two types of 2-inch diameter substrates were used: on (100)\p-Si silicon wafers 10-30 Ohm-cm, University Wafers, thickness 250±25 μm and D263 borosilicate glass (SCHOTT, thickness 500±50 μm). Substrates were initially cleaned with solvents in the order of increasing polarity: acetone, isopropyl alcohol, deionized water. Dilute (4%) hydrofluoric acid was then used to remove the native oxide layer and surface contaminants. The substrates underwent argon and oxygen plasma cleaning to remove organic contaminants in the sputtering chamber at 10 mTorr pressure with 50% argon and oxygen ratio. The Ti films were deposited from a 2-inch diameter, 5N purity Ti target, (Abletarget, China) by DC magnetron sputtering (ATC Orion Series Sputtering Systems, AJA international Inc) with power level 150 W. The distance between the magnetron and the substrate was 24 cm, the pressure of Ar in the chamber during the deposition was 5 mTorr. The films were exposed to nitrogen plasma at 5 mTorr pressure for 30 min at 673K, using the AJA glow discharge option, which utilizes nitrogen plasma discharge glow.

TABLE 1
Depicts the deposition conditions and treatment of the 50
nm titanium seed layers sputtered on (100) Silicon wafers
and D263 borosilicate glass. The layers deposited from a
5N 2″ Ti metallic target, using 150 Watt, 5 mTorr chamber
pressure 30 sccm argon flow and 24 cm deposition height at RT.

| | | Deposition | | N₂, |
|---|---|---|---|---|
| Titanium | | Temperature | Thickness | 400° C. |
| Film | Substrate | [° C.] | [nm] | Soak |
| Ti-1 | Silicon (100) | RT | 50 | — |
| Ti-2 | D263 | RT | 50 | — |
| | Willowglass | | | |
| T-3 | Silicon (100) | RT | 50 | V |
| Ti-4 | D263 | RT | 50 | V |
| | Willowglass | | | |

### Example 2

Sample Preparation: Al_{0.75}Sc₀₋₂₅N Thin Films

Diced aluminum scandium nitride films were sputter-deposited at 200-400° C. substrate temperature [“ASN” samples, Table 2] on the aforementioned Ti seed layers. The films were deposited from a single 3″ 5N metallic alloyed target, 25% scandium 75% aluminum at 250 Watt. Deposition height was 24 cm, chamber pressure set to 5 mT, with 10 sccm Argon and 25 sccm Nitrogen flow. A top titanium 100 nm thick electrode was then deposited.

Samples ASN1-3 demonstrate the effect of temperature on texture, abnormally oriented grain (AOG) formation and subsequent piezo-response. ASN4 inspected the effect of a thicker titanium seed layer of 300 nm on the emergent texture. For sample for ASN10 an additional layer of aluminum 100 nm was deposited prior to 50 nm Titanium, to inspect the effects on texture. Samples ASN8,9 used the same procedure on two different substrates to demonstrate the universality of the process.

The top Ti contact was deposited, patterned and diced into cantilevers of 1×4 cm² in size. The cantilevers were mounted on brass extensions to the bottom electrode. The top electrode was connected with a copper wire, glued with a conductive silver paint. To perform deflection measurements, the cantilevers were then connected to a curvature measurement setup described below.

In another embodiment Al_{0.75}Sc_{0.25}N films were deposited by DC reactive sputtering from metallic alloy targets on the Ti-seeding layers prepared. 250 W power was applied to a 3-inch diameter magnetron loaded with 5N metal alloy targets (Abletarget, China). The pressure in the chamber was 5 mTorr and the ratio between argon and nitrogen was 1:4.

TABLE 2
Depicts the deposition conditions and treatment of the Al_{0.75}SC_{0.25}N
films sputtered on (100) silicon wafers and D263 borosilicate glass.
The layers deposited from a 3″ 25% Sc, 75% Al alloyed target,
using 25 Watt, 5 mTorr chamber pressure 5 sccm argon, 20 sccm
nitrogen flow and 24 cm deposition height at 200-400° C.
The deposition temperature profile for samples ASN8-ASN10
listed in Table 2 was: sputtering for 30 min at 673K
(400° C.) followed by sputtering for 8-13 hrs.
at 523K (250° C.).

| | | | Deposition | |
|---|---|---|---|---|
| (AlSc)N | | Preliminary | Temperature | Thickness |
| Film | Substrate | Layer | [° C.] | [μm] |
| ASN1 | Silicon (100) | Ti 50 nm | 400 | 2 |
| ASN2 | Silicon (100) | Ti 50 nm | 300 | 2 |
| ASN3 | Silicon (100) | Ti 50 nm | 250 | 2 |
| ASN4 | Silicon (100) | Ti 300 nm | 200 | 2 |
| ASN8 | Silicon (100) | Ti 50 nm | 400 then 250 | 3 |
| ASN9 | D263 Borosilicate | Ti 50 nm | 400 then 250 | 3 |
| | glass | | | |
| ASN10 | Silicon (100) | 100 nm Al + | 400 then 250 | 2 |
| | | Ti 50 nm | | |

### Example 3—Microstructure Characterization

In some embodiments of the present example, characterization of the microstructure layers on silicon and Willowglass was performed by scanning electron microscopy (SEM, Sigma, Carl Zeiss, and Zeiss Supra 55VP ,4-8 keV) which provided the layer thickness, grain sizes, surface and cross-section morphology. Nanoscale topography measurements were acquired by atomic force microscopy (AFM), using a Multimode AFM (Bruker), in PeakForce Tapping mode with PNP-TRS probes (NanoWorld), or in Tapping mode with NSG30_SS probes (ScanSens).

Elemental analysis was performed by energy dispersive x-ray spectroscopy (EDS). The Bruker FlatQUAD (four quadrants) EDS is installed on the Zeiss Ultra 55 scanning electron microscope (SEM). Hypermaps of the samples were acquired at 8 kV with a 30 μm aperture and the quantification of the full map or different regions of interest (ROIs) were done using the Bruker Quantax software. The quantification is based on the standardless method with the ZAF matrix correction, background subtraction and spectrum deconvolution used to assess stoichiometric ratios. X-Ray Diffraction (XRD) measurements were carried out in reflection geometry using a TTRAX III (Rigaku, Japan) diffractometer equipped with a rotating Cu anode, operating at 50 kV/200 mA. A graphite monochromator and scintillation detector were aligned in the diffracted beam. The measurements of the films were performed in two reflection modes. First, specular diffraction (θ/2θ scan) that probes only crystallographic planes parallel to the plane of the film was made in Bragg-Brentano geometry. Then, an asymmetric 20 scan with a fixed incident angle of 3 degree was performed using quasi-parallel X-ray beam formed by a multilayered mirror (CBO attachment, Rigaku). It should be noted that under these scanning conditions, each diffracted plane (hkl) is at an angle (θhkl-3) degrees to the plane of the film.

To ascertain the likely-preferred orientation of the crystallites of the (AlSc)N films, which appears in the diffraction patterns obtained under specular conditions, pole figures of the [002] reflections were recorded at the corresponding Bragg angle. For this purpose, a Multi-purpose Attachment III (Euler cradle) was used that performed in-plane sample rotation at regularly increasing sample tilt (ΨP angle) with respect to incident/diffracted beam plane. Shultz slit limited the footprint of X-ray illumination extended due to samples tilt. Qualitative phase analysis was made using the Jade Pro software (Materials Data, Inc.) and PDF-4+2020 database (ICDD). The pole figures were analyzed using Pole Figure Data Processing software (Rigaku).

Wafer curvature measurements were carried out on the wafer's backside, prior and subsequent to deposition, using Dektak 6M profilometer, utilizing a diamond 12.5 μm stylus with a programmable two-point leveling software. A circular radius fit was applied using Origin 2018, from which the in-plane stresses were extracted using Stoney Formula.

### Example 4

### Electromechanical Characterization

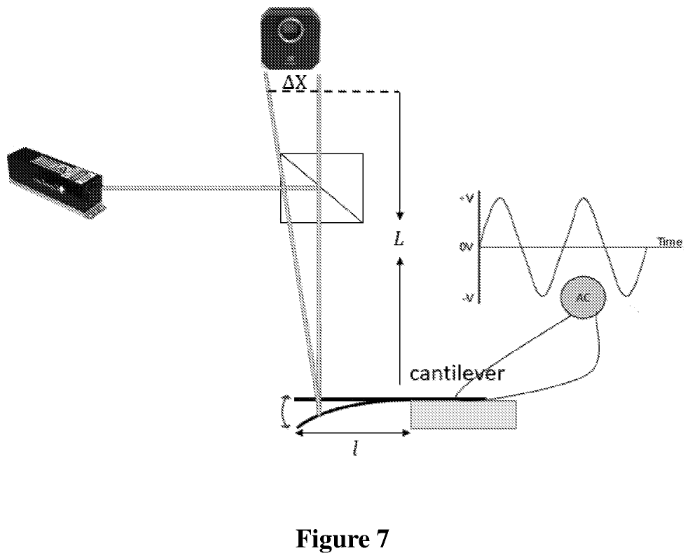

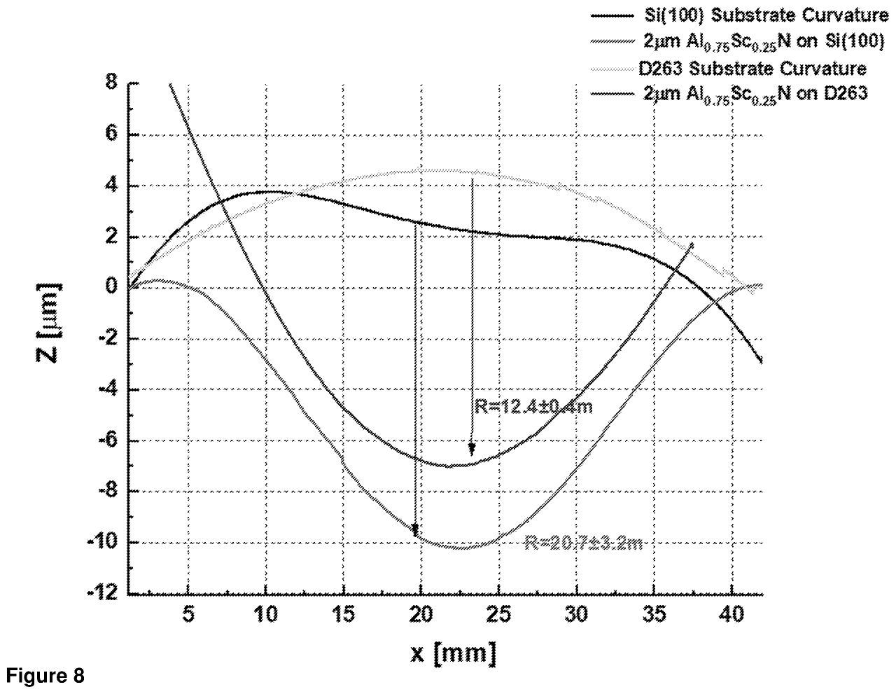

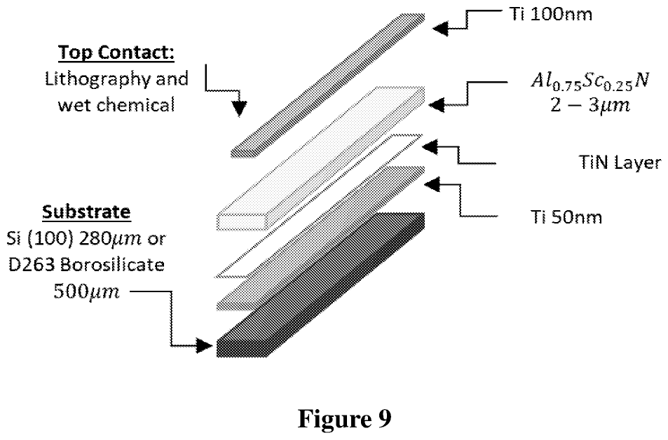

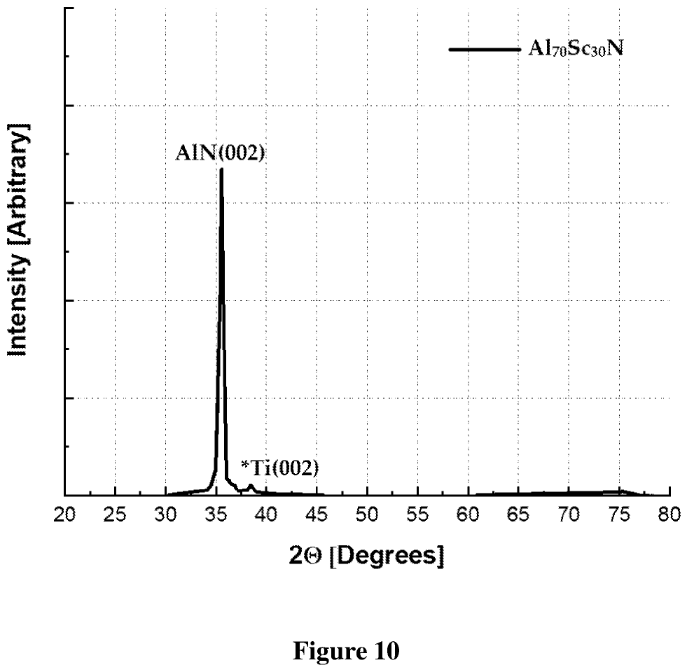

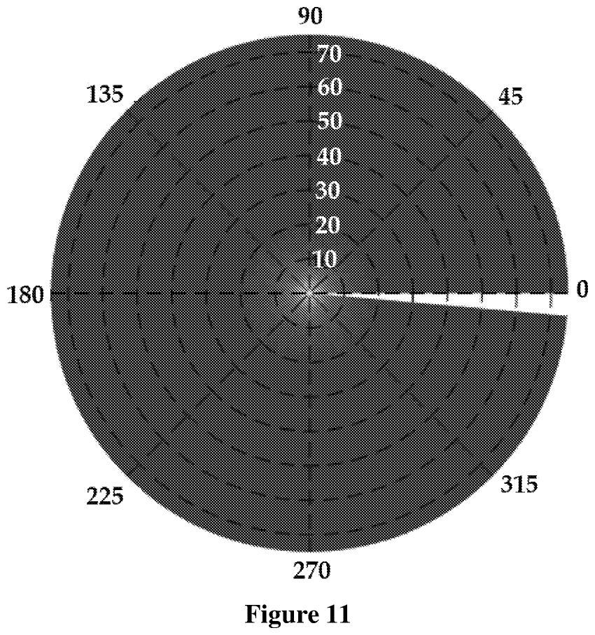

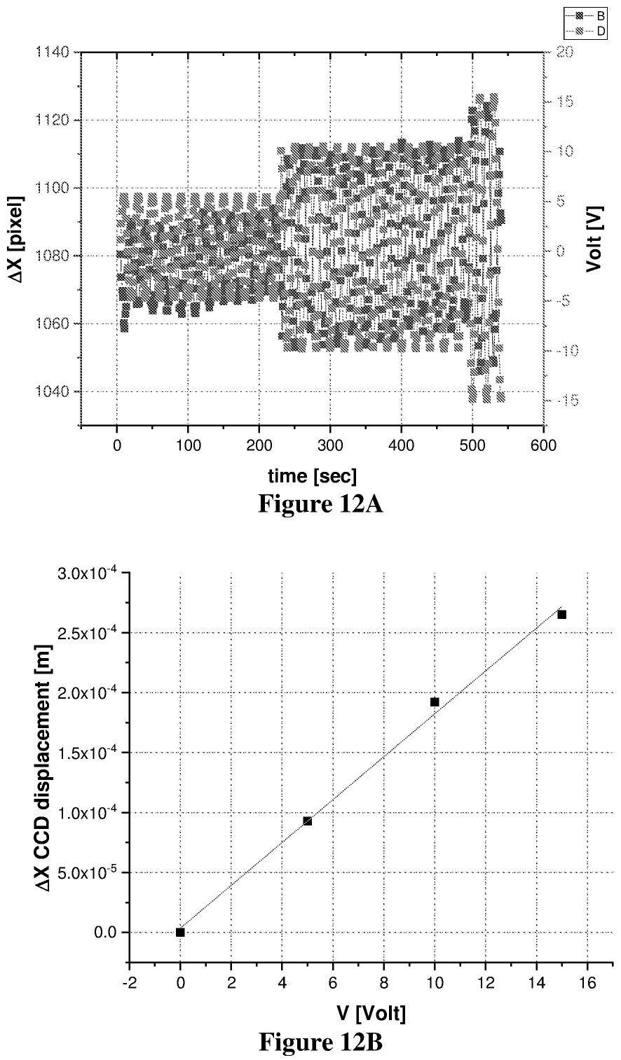

The curvature measurement set up (FIG. 7) was utilized to measure the stresses in the film, and by that the electromechanical response. Applying a voltage using function generator (Rigol, 4062) induces strain in the (AlSc)N piezoelectric layer which results in the bending of the cantilever. The displacement of the laser beam ΔX is multiplied by a conversion factor (7.5 Mm/Pixel) yields the actual beam displacement from which the curvature was extracted using equation (1):

$$Δ k = \frac{2 \cdot Δ X}{L \cdot l} \qquad ( 1 )$$

where Δk is the change in curvature; L is the distance from the sample to the CCD camera; l is the distance from the reflection point to the anchored point. From the change in curvature Δk, the stress, Aa, in the film can be calculated according to the Stoney's Formula, equation (2):

$$Δ σ = \frac{{Y}_{s}}{1 - {v}_{s}} \frac{{t}_{s}^{2}}{6 {t}_{f}} \qquad ( 2 )$$

where Yₛ is the Young's modulus of the substrate; vs is the Poisson's ratio of the substrate. tₛ and t_{f} are the thickness of the substrate and film respectively. One can extract the piezolectic coefficient

$${e}_{31} [ \frac{c}{{m}^{2}} ] ,$$

describing charge density, by dividing the calculated stress by applied electric field E, equation (3):

$${e}_{31} = \frac{Δ σ}{E} ; \qquad ( 3 )$$

### Example 5

### Deposition and Microstructure

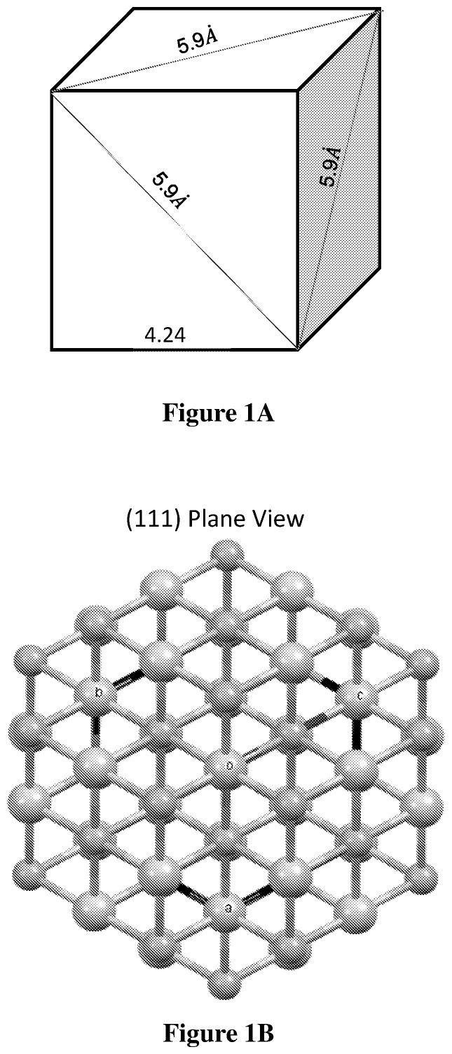

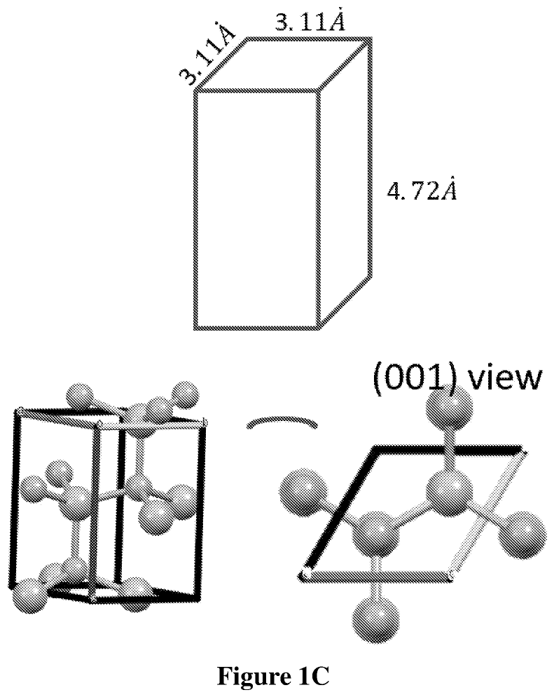

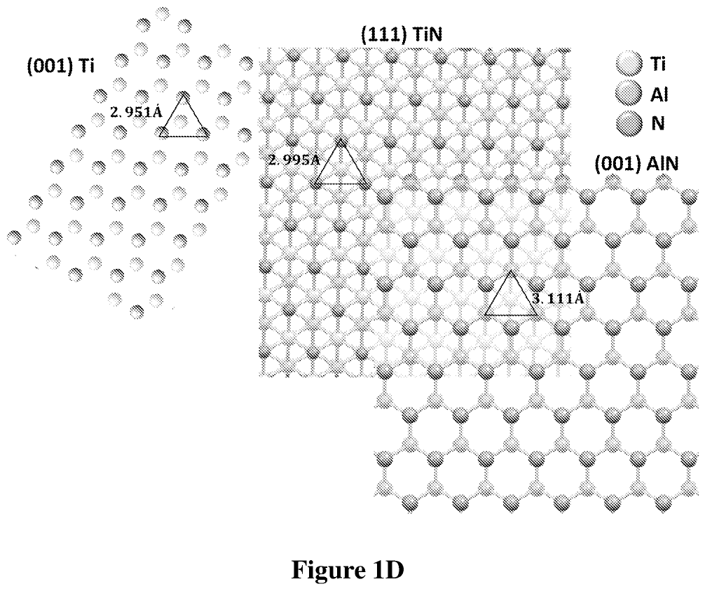

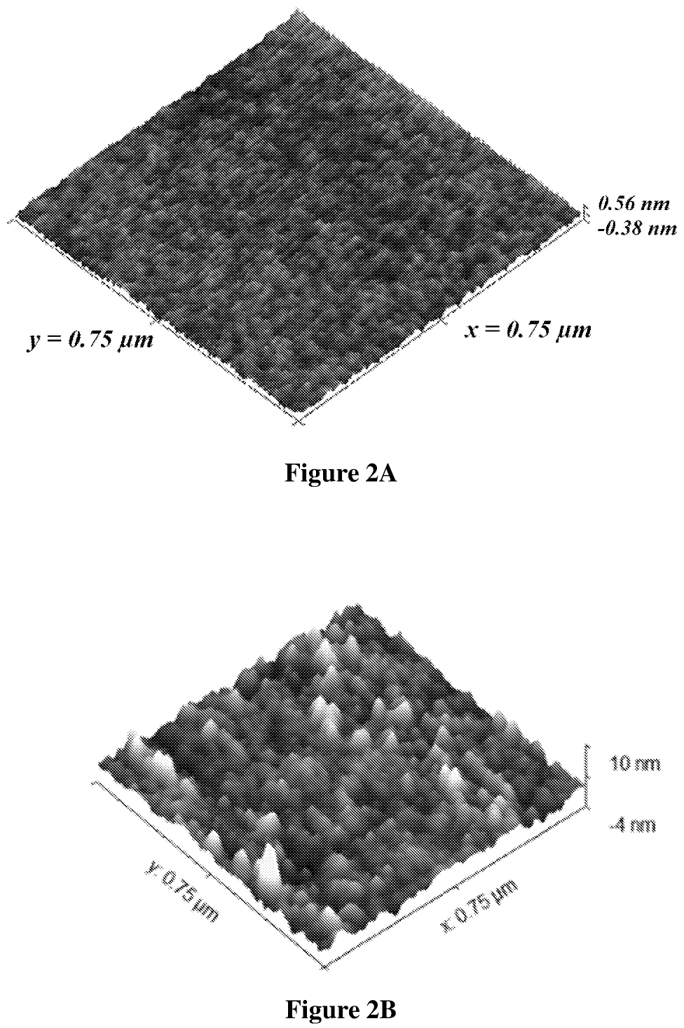

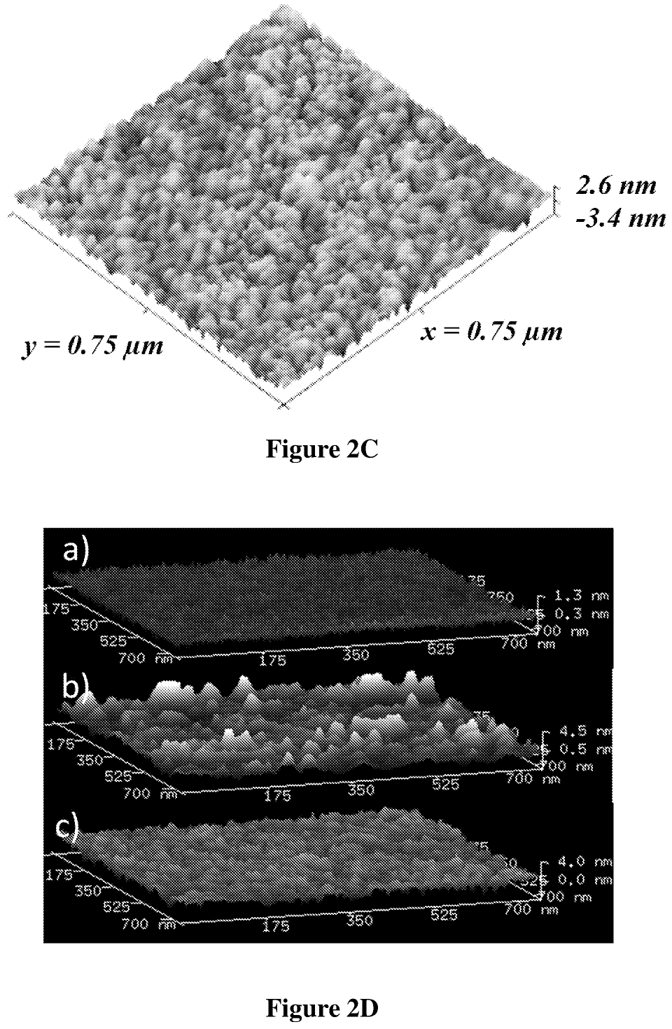

Topographic AFM measurements shows a clear trend of surface smoothening as a result of exposure to nitrogen at high temperature [FIGS. 2A-2D]. Such surface smoothening indicates a reaction at the sample surface, which correlates with the corresponding XRD spectra. Titanium nitride has a rock-salt structure [FIG. 1A] with a (111) preferred growth orientation [FIG. 1B]. This exposed (111) plane comprised of equilateral triangles with ˜5.9 Å faces provides local nucleation points for the hexagonal 3.1 Å faced grains of (AlSc)N [FIG. 1C]. These local, low density nucleation points double as a reactive-epitaxial layer which ensures columnar, stress-free grain growth, for the subsequent (AlSc)N deposition. FIG. 1D shows three surface layers presenting small epitaxial mismatch. The first is a Ti(001) plane, comprising equilateral triangles 2.951 Å on a side. The second is the TiN (111) plane, comprising equilateral triangles 2.995 Å on a side. Each TiN nucleation site provides in-situ epitaxy for superimposed AlN (001) plane, comprising equilateral triangles 3.111 Å on a side.

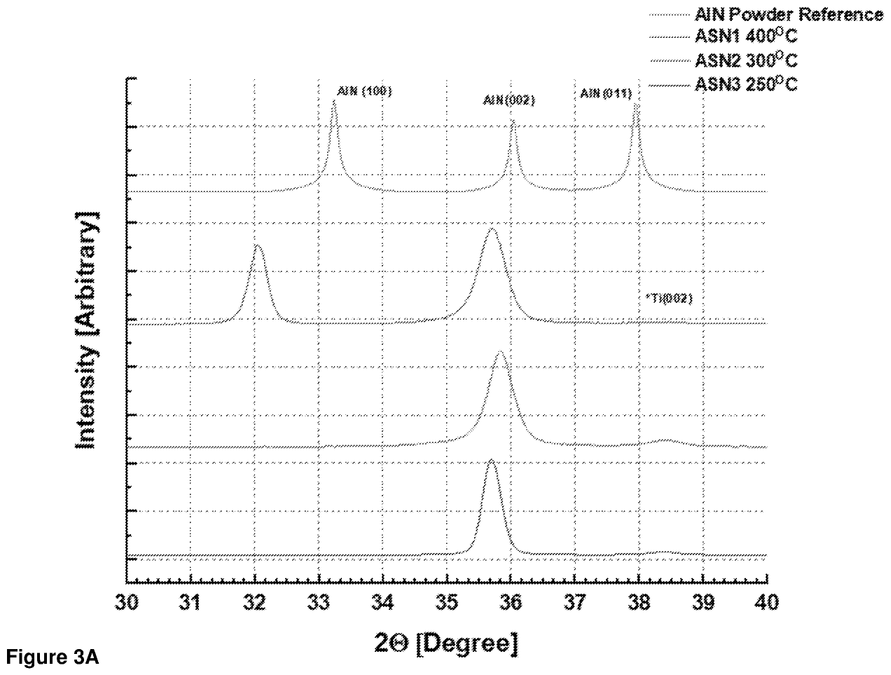

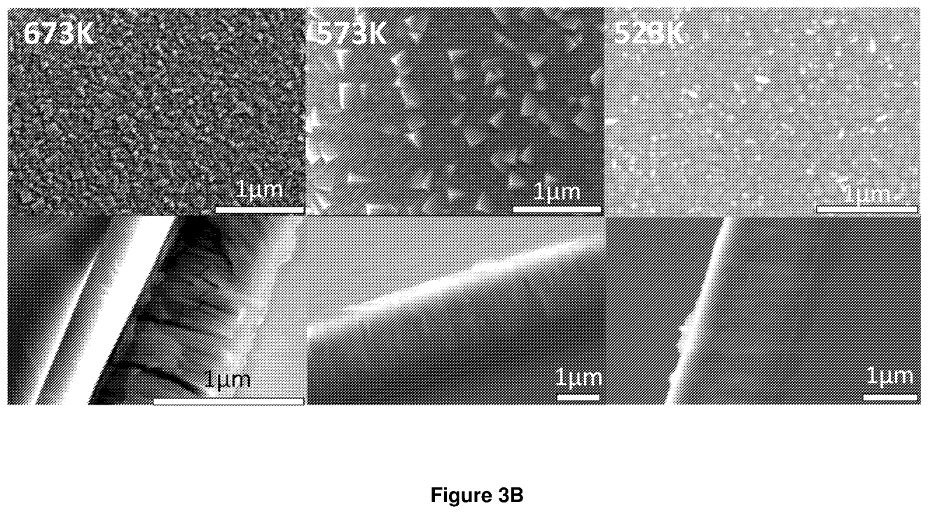

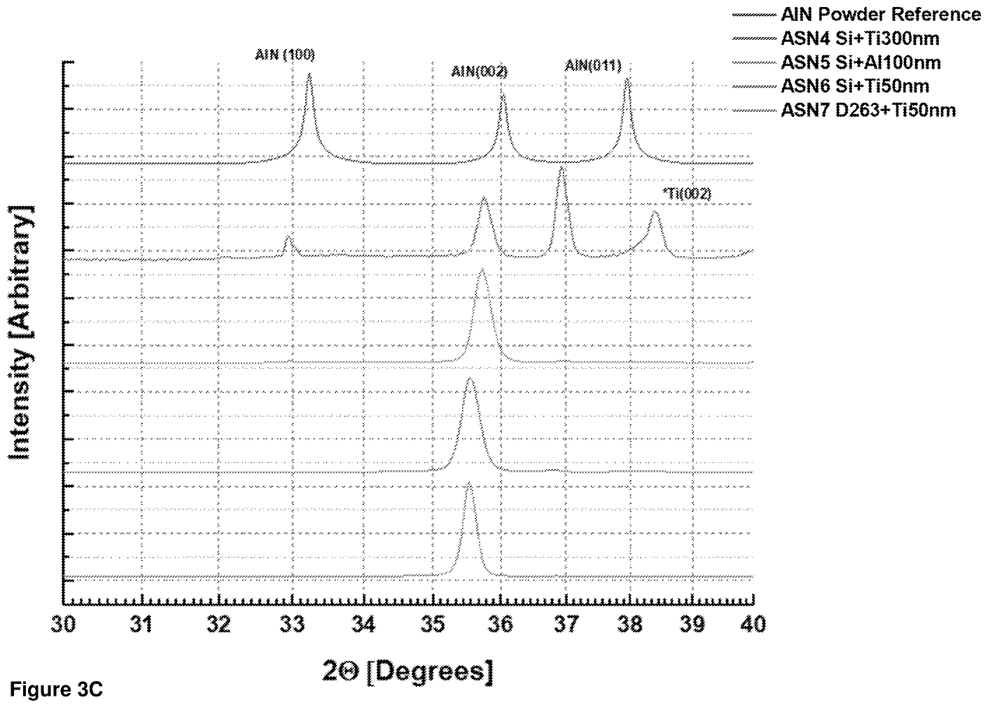

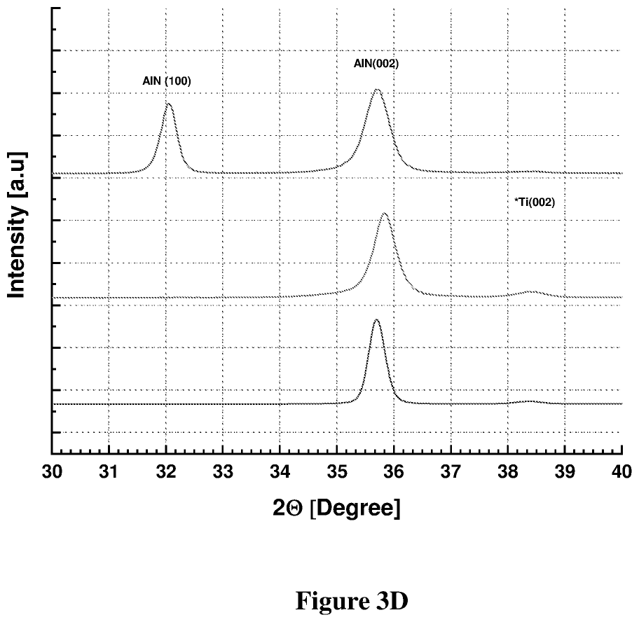

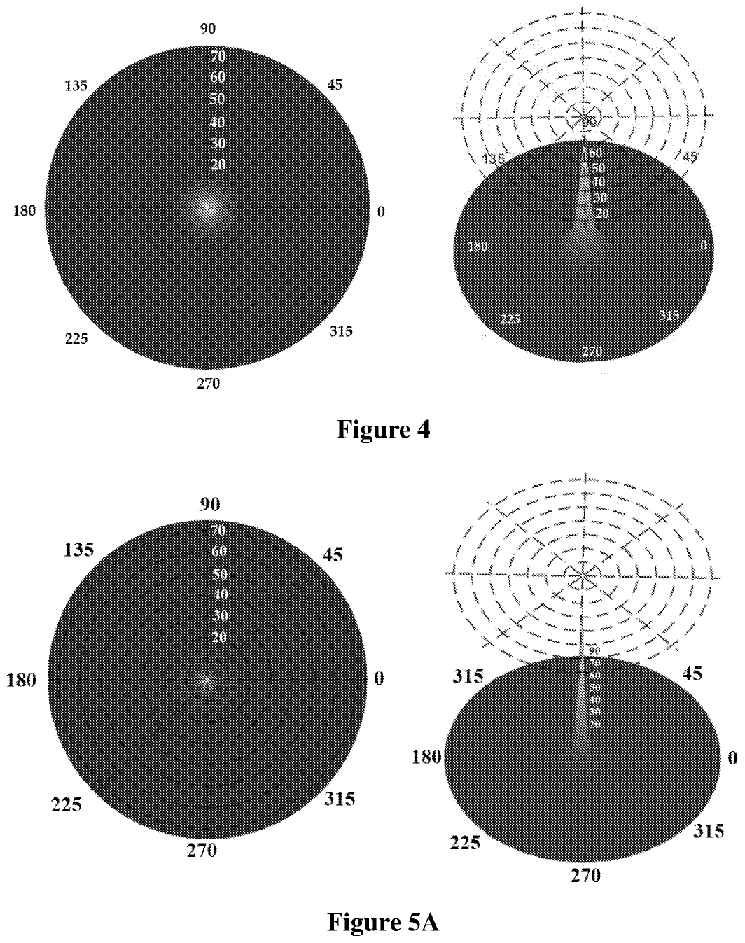

FIG. 3A Depicts the XRD spectra of films ASN1-3 of Table 2, wherein the films were grown at 400° C., 300° C. and 250° C. and the corresponding surface and cross-section imagery are displayed in FIG. 3B. The SEM images depict a clear trend—a reduction of AOGs on the sample surface with reduction in deposition temperature. The (002) AlN peak(36.04°) is shifted in the films, a shift to lower angles indicating lattice expansion. Such expansion can be attributed to scandium incorporation to the wurtzite lattice and to film deposition stress.

The (002) c-axis texture is characterized by hexagonal grains and columnar growth evident in film samples ASN2,3 of Table 2. The peak (32.05⁰) attributed to (100) AlN seen in ASN1 (Table 2) suggest a loss of orientation occurred during deposition. This is also backed by the abundance AOGs, pyramidal shaped grains seen on the surface. This loss of orientation is attributed to Sc segregation and is evident by AOG's on ASN1's surface and the brittle columnar growth shown at the cross-section imagery. In an effort to reduce the scandium from segregating and to lock it kinetically in the wurtzite phase, the deposition temperature was reduced. Samples ASN2-3 (Table 2) deposited at 300° C. and 250° C. displayed a single (002) XRD peak with a clear suppression of AOG formation on the sample surface and cross-section.

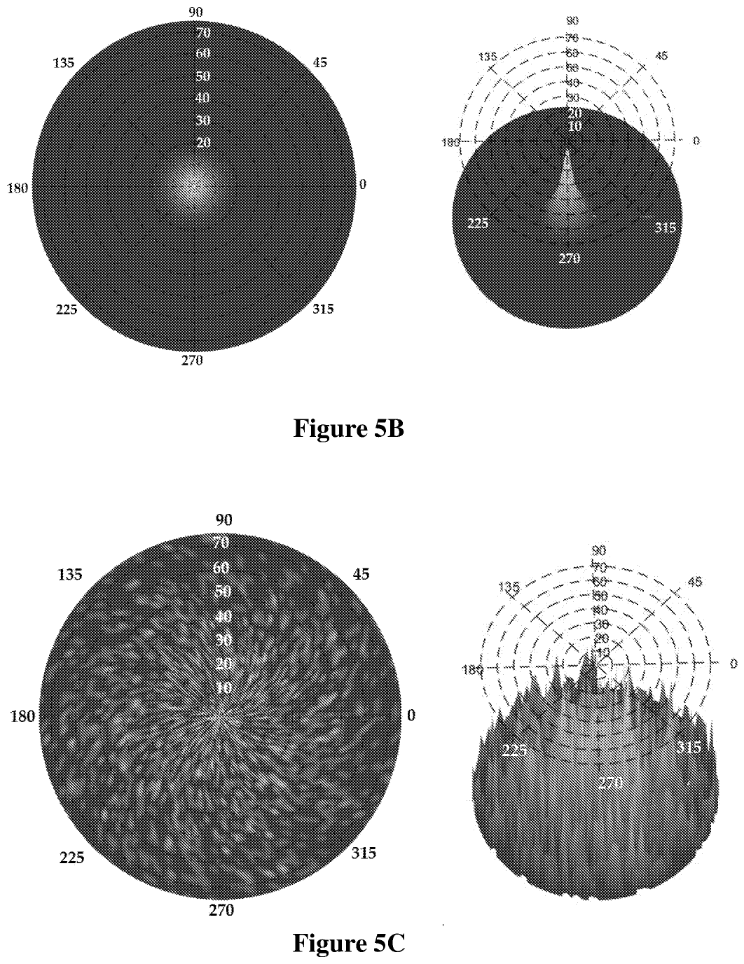

Samples ASN4,8,9,10 from Table 2 [FIG. 3C] depositions were conducted with modifications to the substrate, seed layer thickness, preliminary aluminum layers, temperature and (AlSc)N film thickness. Such modifications were vital to understand the growth mechanism. Samples ASN 8-9 (Table 2) were deposited at 200° C. on 50 nm Ti seed layer on two different substrates D263 borosilicate, an amorphous material and (100) silicon wafers. A singular (002) peak indicative of texture is observed in the corresponding XRD spectra [FIG. 3C, red, purple]. Pole-figure measurements of samples ASN8,9 (002) peak were conducted to investigate the degree of texture. FIGS. 5A and 5B which demonstrate that 3 μm thick layers of AlScN can be deposited on Si and borosilicate glass to a high degree of texture. A singular peak resulted with no apparent residues of other orientations is observed. Such absolution indicates a high degree of texture. Since similar results were observed from two different substrates one can deduce that the process utilizing Titanium seeds for (AlSc)N deposition is substrate independent.

To investigate this hypothesis, changes were carried out for the titanium seed layers of film samples ASN 4,10 (Table 2). Film sample ASN4 utilized a thicker titanium seed layer of 300 nm, while sample ASN10 was grown on 50 nm titanium with a preliminary 100 nm aluminum layer. Sample ASN4 XRD spectra displayed multiple peaks, indicative of a loss of preferred orientation. This is backed by the multiple observed peaks of the corresponding pole figure [FIG. 5C]. This suggests that the thickness, and topography of the titanium seed layer plays a significant role in the growth process of oriented (001) (AlSc)N. Sample ASN10's XRD spectra demonstrated a singular (002) peak, though a minor widening of the (002) peak is visible by the pole figure (FIG. 5B) indicating a minor loss of texture in relation to the plane occurred.

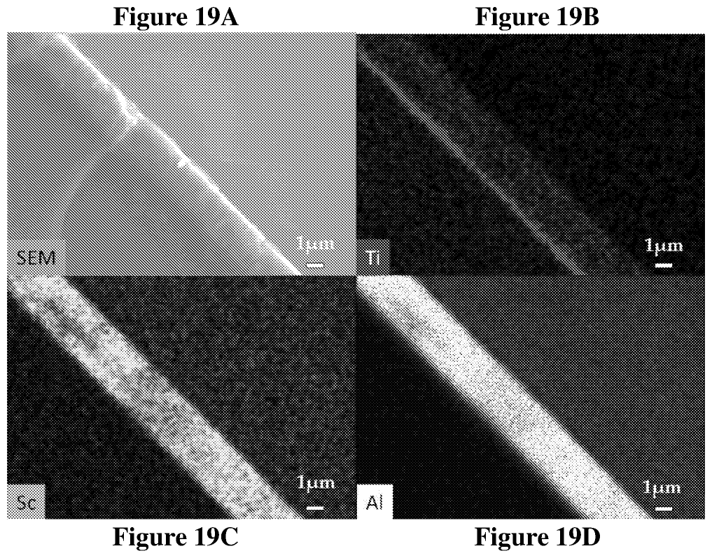

EDS chemical mapping was carried out using 4 and 8 kV of sample ASN9 [FIG. 19] and was conducted to investigate the chemical distribution of aluminum and scandium throughout the samples. The resulting chemical mapping demonstrated homogenous distribution of Al and Sc. This suggests that a singular phase of material exists within the film.

### Example 6

### Electromechanical Characterization

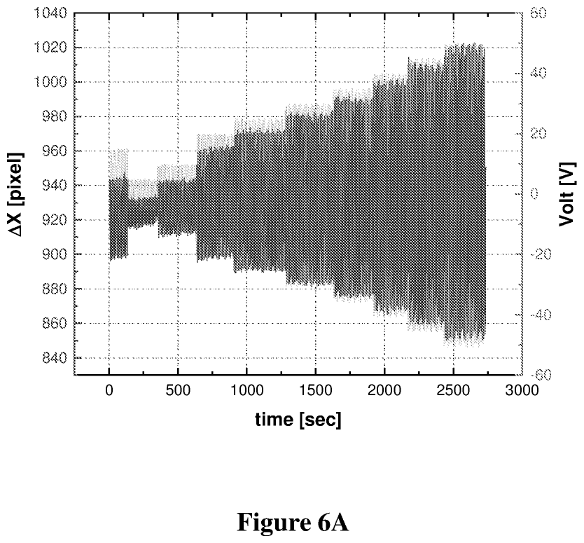

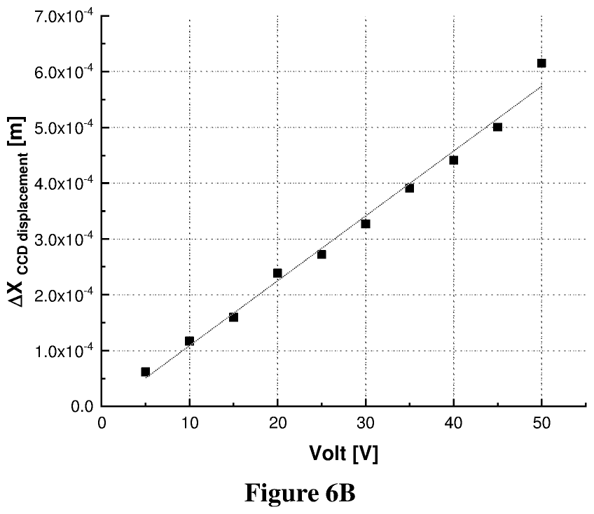

Application of a sinusoidal alternating bias up to 20 Vpp at 0.1 Hz generated a first harmonic response, a vertical displacement of the cantilever with the voltage applied (FIG. 6A), indicative of piezoelectricity. This behavior was observed throughout all tested films, with the exception of sample ASN1 which produced no response. The stresses in the films were calculated by the cantilever's displacement (Eq.1). Dividing the stresses by the applied field resulted the piezoelectric coefficient e₃₁, see equation (3).

The resulted films generated a piezoelectric response as high as high as about 2.5 C/m². We demonstrated that AOG formation is greatly affected by deposition temperature, and consequently the film orientation, which affects the piezoelectric response.

(AlSc)N were deposited with a large thickness and high degree of orientation on two substrates of different crystallographic nature: (100) oriented silicon and amorphous borosilicate glass. The same quality of film resulted when a preliminary layer, such as 100 nm of aluminum, was present underneath the 50 nm titanium seed. It should be noted that a titanium seed layer of 300 nm resulted in a complete loss of orientation, which suggests that the growth process requires a degree of topographical smoothening in addition to that of epitaxy.

To investigate the evolution of the Ti seed layer during deposition XRD measurements were performed on a 50 nm Ti seed layer which was soaked at nitrogen at 400° C. (

In another embodiment of this example all gasses used were of 6N purity and were supplied by Gas Technologies Israel. HF (hydrofluoric acid), organic solvents, acetone and isopropyl alcohol (IPA), of semiconductor grade (CMOS, Sigma Aldrich), were used for cleaning substrates. Furthermore, 50 nm thick titanium films were deposited by sputtering, keeping the substrate at room temperature. Two types of 2-inch diameter substrates were used: on (100)\p-Si silicon wafers 10-30 Ohm-cm, University Wafers, thickness 250±25 μm and D263 borosilicate glass (SCHOTT, thickness 500±50 μm). Substrates were initially cleaned with solvents in the order of increasing polarity: acetone, isopropyl alcohol, deionized water. Dilute (4%) hydrofluoric acid was then used to remove the native oxide layer and surface contaminants. The substrates underwent argon and oxygen plasma cleaning to remove organic contaminants in the sputtering chamber at 10 mTorr pressure with 50% argon and oxygen ratio. The Ti films were deposited from a 2-inch diameter, 5N purity Ti target, (Abletarget, China) by DC magnetron sputtering (ATC Orion Series Sputtering Systems, AJA international Inc) with power level 150 W. The distance between the magnetron and the substrate was 24 cm, the pressure of Ar in the chamber during the deposition was 5 mTorr. The films were exposed to nitrogen plasma at 5 mTorr pressure for 30 min at 673K, using the AJA glow discharge option, which utilizes nitrogen plasma discharge glow.

Table 1) on both silicon and D263 substrates. Peaks were observed at (36.65° C.) which developed after exposure to nitrogen at high temperatures. This peak can be attributed to (111) TiN (36.8⁰) and provides a good epitaxial match to the (001) hexagonal (AlSc)N. This might also provide an explanation as to the suppression of AOGs, if the resulting epitaxial match between (AlSc)N and Ti is created in-situ during deposition it will contribute significantly to a reduction in deposition stresses, thereby reducing scandium segregation and preventing the emergence of abnormally oriented grains (AOGs).

### Example 7

### Measurements of the Piezoelectric Coefficient

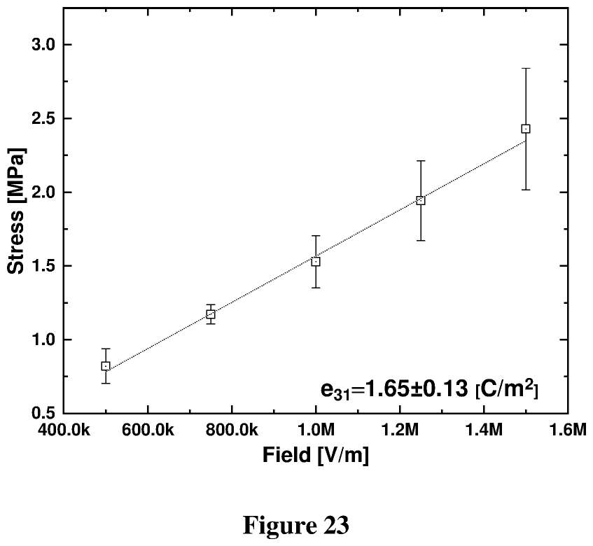

Regarding samples ASN8, ASN9 and ASN10 of Table 2, the resulting substrate\Ti\Al_{0.75}Sc_{0.25}N film stacks were covered with a 50 nm thick top titanium layers served as a top electrode. Samples with the substrate/Ti/Al_{0.75}Sc_{0.25}N/Ti film stacks were cut into rectangular 1 cm wide and 2-4 cm long plates. The latter were mounted as cantilevers in a setup monitoring deflection and voltage applied between the top and bottom Ti layers. The piezoelectric coefficient was calculated from the stress induced in the cantilever due to voltage application. The stress was deduced using Stoney formula under assumption of purely cylindrical bending (zero Gaussian curvature). For ASN8-10 samples the piezoelectric coefficient was, on average, e₃=1.65±0.13 C/m² (see FIG. 23).

According to some embodiments of this example, the film characterization is as follows:

The thickness of each film in the stack was deduced from the images of stack cross section acquired with a scanning electron microscope (SEM, Sigma, Carl Zeiss, and Zeiss Supra 55VP, 4-8 keV). SEM images were also used to estimate grain size and morphology of both surface and cross-section. Nanoscale topography maps were acquired with an atomic force microscope (Multimode AFM (Bruker) in the Peak Force Tapping mode.

Elemental analysis was performed with energy dispersive X-ray spectroscopy (EDS) with a Bruker FlatQUAD (four quadrants) EDS attachment installed on the Zeiss Ultra 55 scanning electron microscope. EDS spectra were collected with 8 kV e-beam acceleration voltage.

X-ray powder diffraction (XRD) patterns were collected with a TTRAX III diffractometer (Rigaku, Japan) in Bragg-Brentano geometry. To detect the film texture, pole figures of the diffraction peaks were recorded at the corresponding Bragg angle using an Euler cradle in the Rigaku TTRAX diffractometer. A Shultz slit was used to limit the footprint of the extended X-ray illumination spot due to sample tilt. Phase analysis was made using Jade Pro software (Materials Data, Inc.). In addition to the (002) diffraction peak of Al_{0.75}Sc_{0.25}N, examining c-axis texture, pole figure data were collected for the (100) and (011) directions. However, the diffracted intensity in these peaks was too weak to be detected, thus we estimate that they are at least 500 times weaker than the (002) peak.

Stress in the films was deduced from the changes in the wafer curvature before and after the deposition. Since the Al_{0.75}Sc_{0.25}N films were by far the thickest in the stack, the stress was calculated neglecting the other layers. Wafer curvature was measured with a DektakXT stylus profilometer (Bruker,USA).

Pyroelectric coefficient was measured with a Periodic Temperature Change method (Chynoweth) using a modulated IR laser (wavelength 1560 nm, 12 W/cm² OSTECH, Germany) operating at 17 kHz. To ensure 100% radiation absorption, the 2 mm diameter Ti contacts prepared for these measurements were covered with carbon black, as known in the art.

X-ray photoelectron spectroscopy (XPS) was used for chemical analysis of film surfaces to detect formation of TiN layer and for non-contact probe of the pyroelectric coefficient. Measurements were performed on a Kratos AXIS-Ultra DLD spectrometer, using a monochromatic Al k_{α} source at low power, 0.3-15 W. The sample temperature was monitored by a thermocouple located within the XPS instrument in close proximity to the sample. Scanning was continuous at each temperature in order to obtain a reliable value for the binding energy.

### Example 8

### Formation of TiN on a Ti Seeding Layer

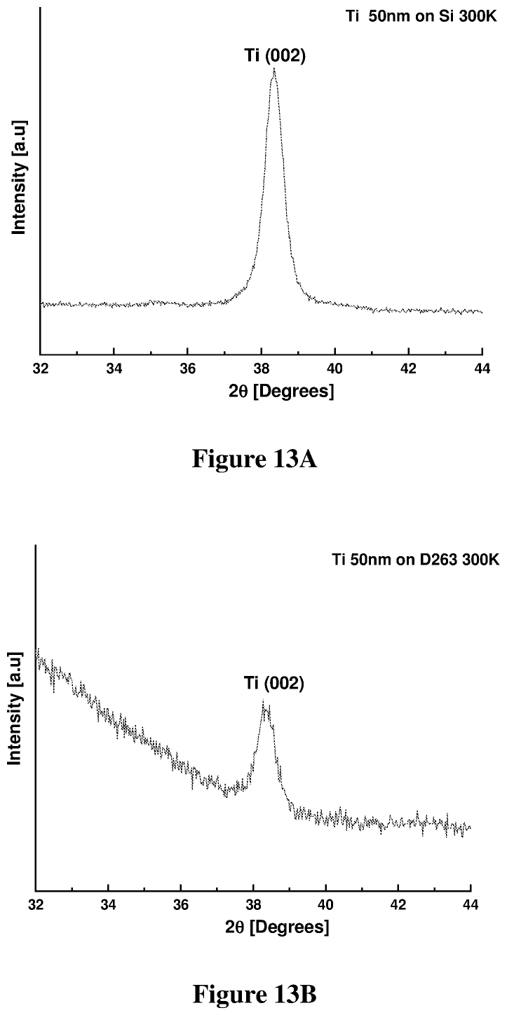

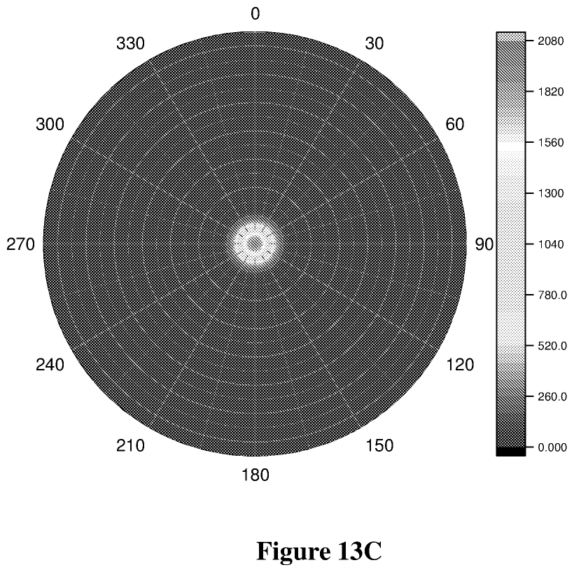

Sputtered Ti is known to grow as α-phase (HCP) with preferred (001) orientation. Therefore, as a seeding layer, 50 nm thick Ti films were deposited by DC magnetron sputtering on both types of substrates as described above. According to XRD, the films are indeed α-Ti with high (001) texture: the (002)-diffraction peak dominates spectra and has FWHM=0.55° forboth substrates (FIGS. 13A-13C).

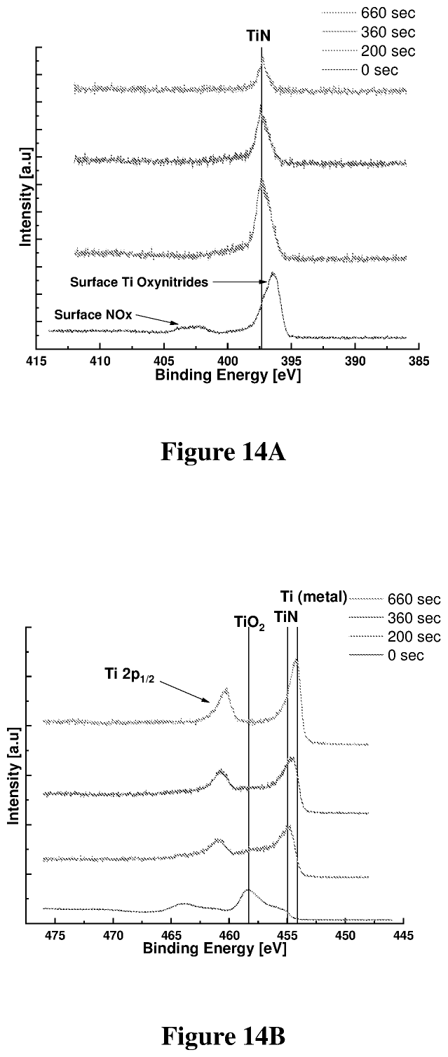

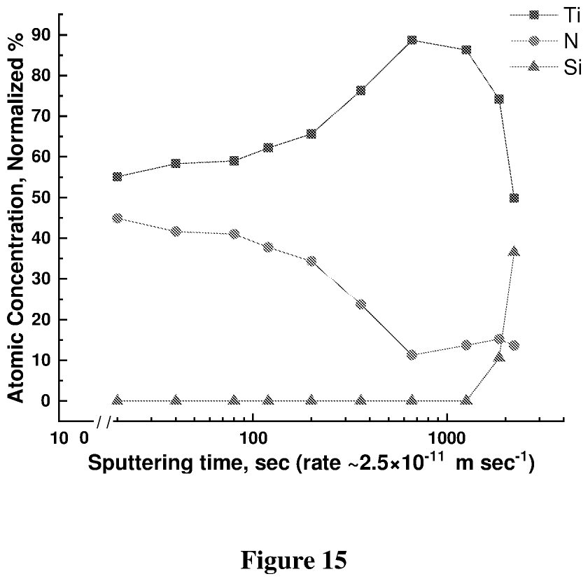

To simulate in-situ formation of TiN that occurs during reactive sputtering of (Al,Sc)N, the films were exposed to the glow discharge nitrogen plasma at 673K for 30 min and their surface was investigated with XPS. Since the top layer can be contaminated or oxidized during the transfer of the films from the sputtering system to the XPS chamber, during the XPS measurements, the samples were sputtered by argon (rate˜1 Å/s). Before the sputtering, the peaks at 396 eV and 400 eV (N is) and 557 eV (Ti 2p), which can be assigned to oxidized TiN, were observed. After removal of ˜1 nm, these peaks are replaced by the peaks associated with TiN, 397 eV (N is) and 455 eV (Ti 2p), see FIG. 14A and FIG. 14B. As the sputtering continues, the intensity of the N is peak decreases and a gradual transition between the TiN and metallic Ti peaks is observed. The sputtering was continued until a silicon signal was detected. From the change in the calculated atomic concentration of the nitrogen with the sputtering time (FIG. 15), we estimate that the TiN layer formed upon exposure of Ti to nitrogen plasma has ˜10 nm thickness. Such a small thickness suggests that it is determined by the diffusion of nitrogen into Ti metal, similar to that found in industrial plasma nitriding.

AFM mapping revealed that the formation of TiN was accompanied by detectible smoothing of the surface (FIG. 2D). The average surface roughness of the deposited Ti films was 1.1 nm; while reaction with nitrogen plasma reduced the roughness to 0.68 nm, which is favorable for growth of (Al,Sc)N.

### Example 9

### Reactive Sputtering of AlScN

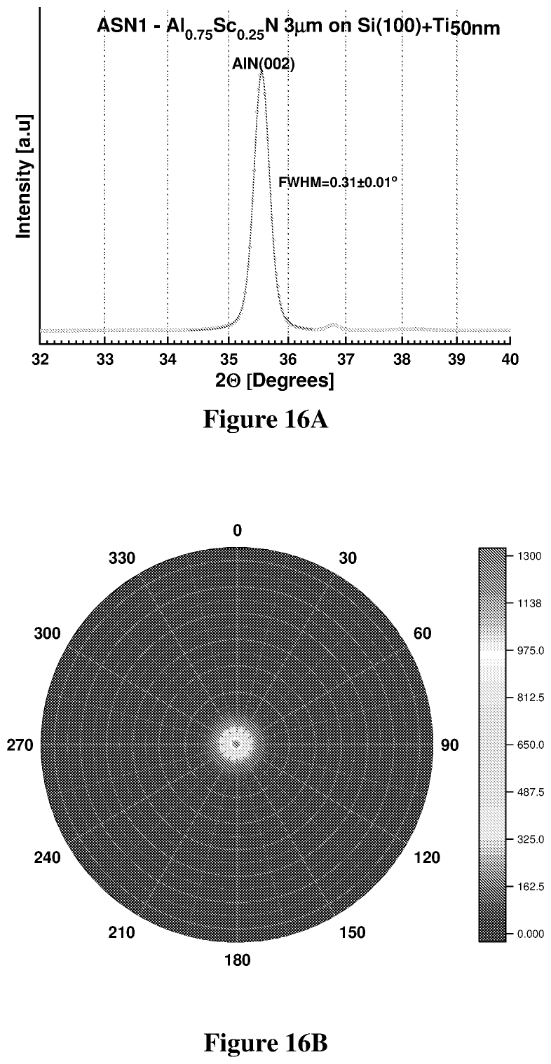

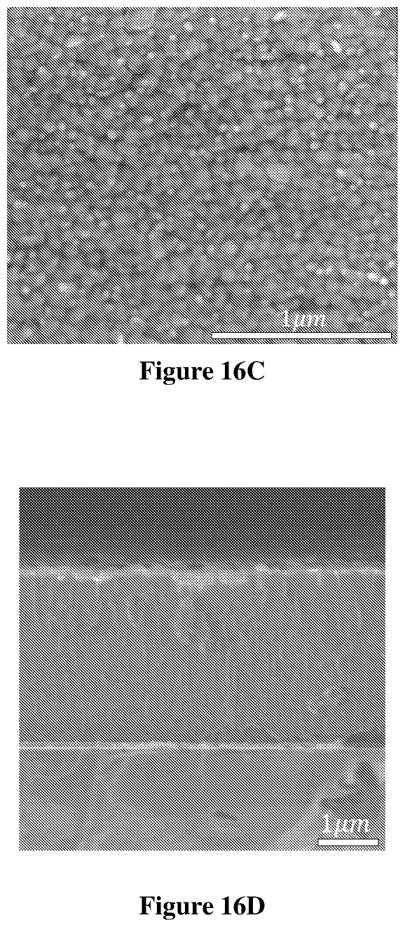

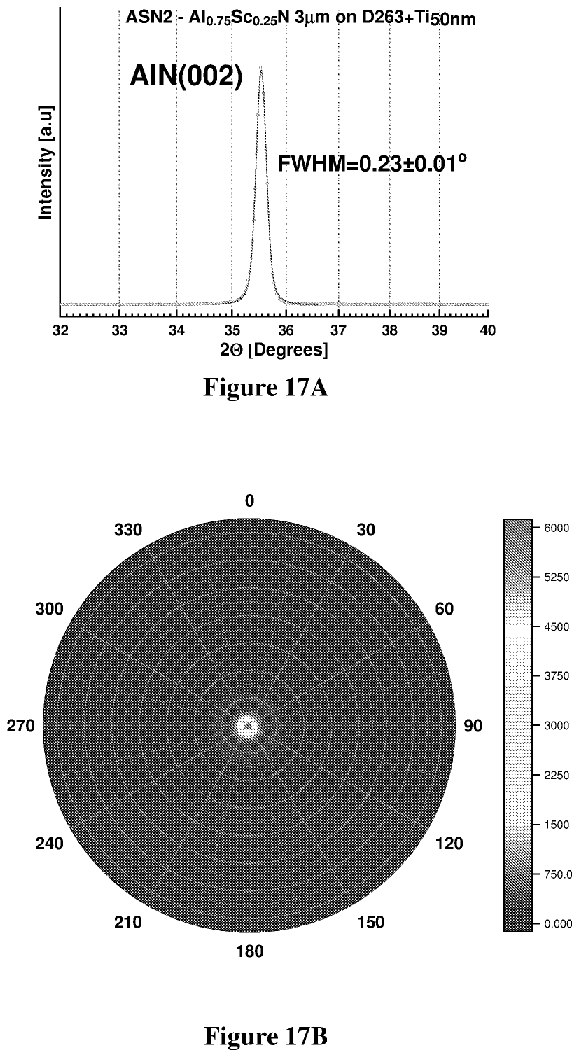

Thin films of Al_{0.75}Sc_{0.25}N were deposited on both types (Si and D263 glass) of the substrates coated with 50±10 nm (001)-textured Ti. Without breaking the vacuum after the deposition of Ti seeding layers, the substrates were then heated up in the sputtering chamber to 673±10 K and reactive DC sputtering from a metallic alloy target, Al_{0.75}Sc_{0.25}, was performed for 30 min in the nitrogen/argon plasma. Then the deposition process continued at 523K for 8-13 hrs. depending on the desired film thickness of 2-3 μm, 3.5 to 4 nm/min deposition rate (FIGS. 3D, 3B). Irrespective of the substrate, (100)-Si or D263 borosilicate glass, films up to 3 μm thick were produced (Table 2, FIG. 16 and FIG. 17).

The XRD patterns of the Al_{0.75}Sc_{0.25}N films contained only the (002) diffraction peak. The pole figure collected for this peak (2θ≈35.5°) has the full width at half maximum height (FWHM) Δ2θ ≈ 0.31±0.02° for both substrates for all azimuthal directions (FIG. 16A,B and FIG. 17A,B).

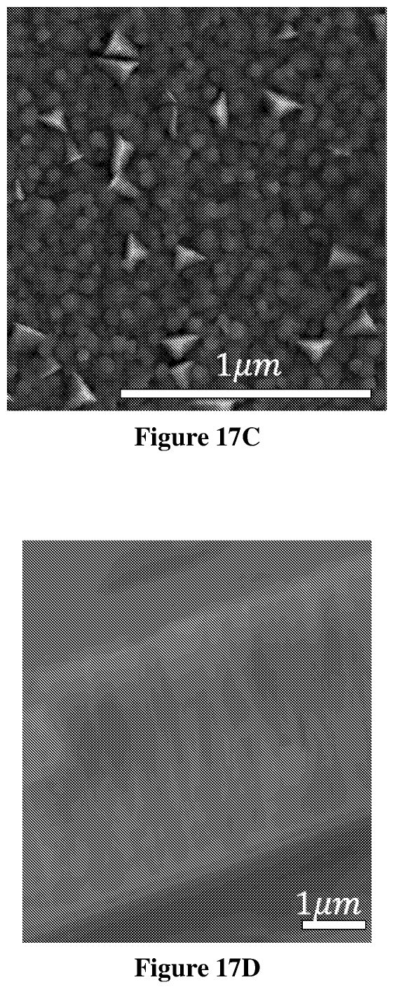

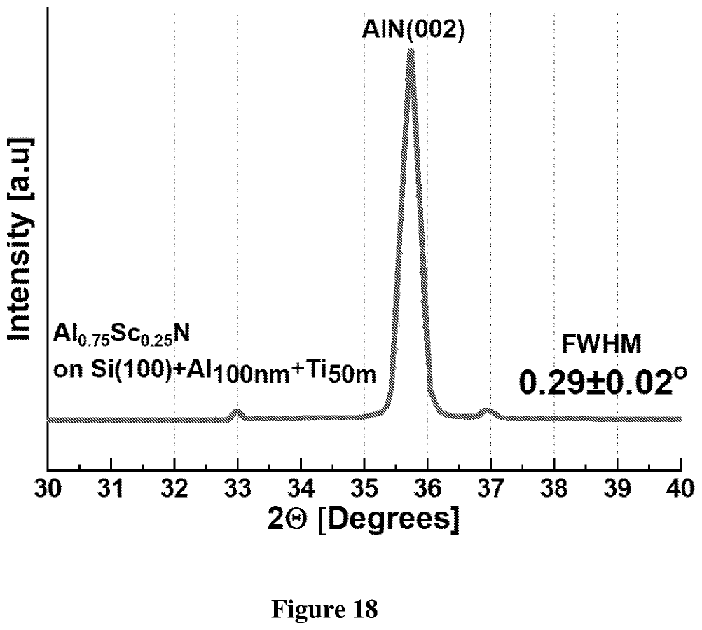

Scanning electron microscope (SEM) images of the film surfaces show pebble-like grains with mean transverse diameter ˜85-100 nm (FIG. 16C, FIG. 17C). Surface contamination and mis-oriented grains occupy <6% of the area as determined from replicate measurements on five Si wafers. It was found that the film quality was not affected by the presence of a 100 nm thick Al layer introduced to promote relaxation of the compressive stress typical for sputtered (Al,Sc)N (FIG. 18). The compressive stress in the all the films, with and without the Al stress relaxation <100 MPa, as calculated from changes in wafer curvature, indicating that Ti\TiN seeding layer leads to low deposition stress. EDS elemental mapping shows homogenous distribution of Al and Sc (FIG. 19).

### Example 10

### Pyroelectric Measurements

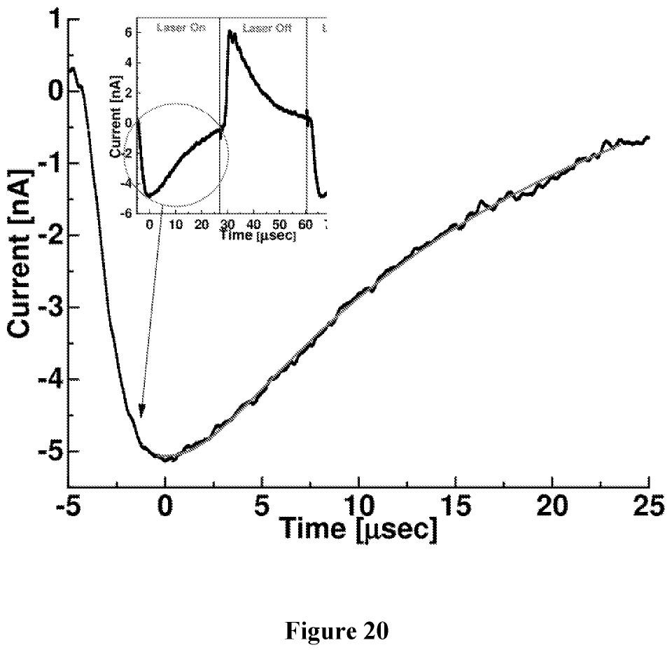

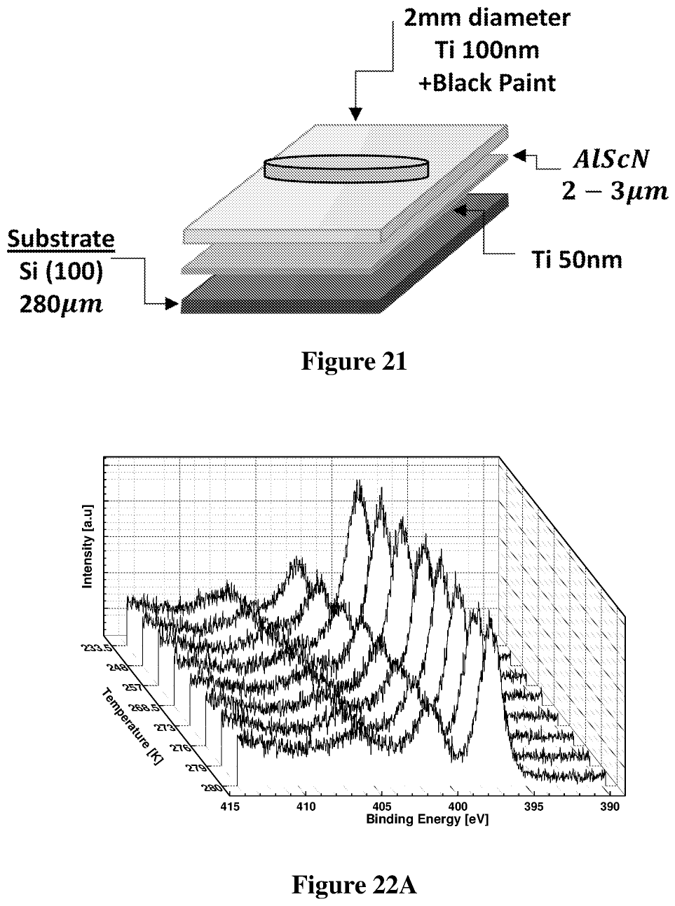

To determine whether the polar axis is directed toward or away from the substrate, i.e. to distinguish between [001] and [001̅)] orientations, we measured the pyroelectric effect with PTC and with XPS-based methods. The PTC measurements revealed that the pyroelectric coefficient is α=−13.9±0.1 [μC/m\hat{ }2 K] (FIG. 20), which is close to that previously reported for this composition (25% Sc). See also FIG. 21 for a schematic of a sample as prepared for pyroelectric measurements with a 2 mm diameter, black-paint coated upper Ti electrode.

We note the following with regards to calculating the pyroelectric coefficient α_{f} from error function fitting. The pyroelectric current j fit to the error function is given by

$${j}_{0} \cdot erf ( \sqrt{\frac{τ}{4 t}} ) .$$

The parameter

$${j}_{0} = \frac{{F}_{d} {α}_{f}}{{c}_{v} ( {d}_{s} + δ )} ,$$

where F_{d}=0.3778 Watt is the effective laser power applied to the sample; α_{f} is the pyroelectric coefficient; cᵥ is the heat capacity of the Si wafer, 1.64×10⁶ Joules/K•m2; the wafer thickness, dₛ=280 μm; δ=2 μm is the thickness of the (Al,Sc)N layer.

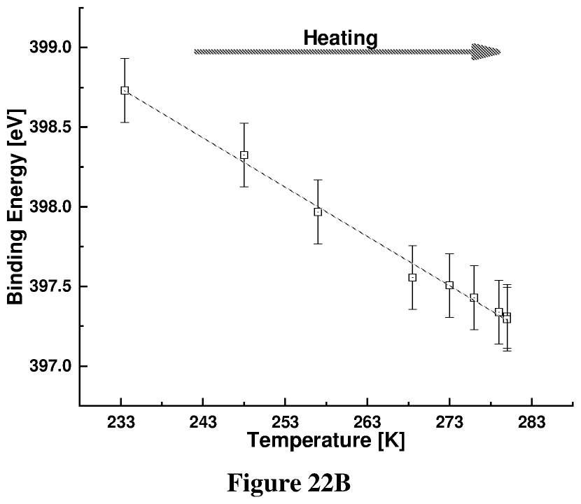

However, in our case a is negative. In the XPS measurements, the N is peak shifts to lower energies upon heating and vice versa (FIG. 22) providing further support that the pyroelectric response is negative. The sign of the pyroelectric response suggests that the films are [001] oriented, i.e., the top surface is Al-terminated. This is in contrast to previous reports on films grown on inert metallic seeding layers, all of which are N-terminated. The fact that the films prepared in the current study are Al-terminated agrees with the proposed nucleation mechanism that the growth of the (Al,Sc)N Wurtzite structure begins from an N-terminated face of TiN.

### Example 11

### Piezoelectric Measurements

On average, the transverse piezoelectric coefficient deduced from the cantilever deflection data was e₃₁=1.65±0.13 C/m². This value is similar to those reported in literature for films <1 μm thick, with the same Sc concentration (25 mol % Sc), see FIG. 23. On average, the transverse piezoelectric coefficient deduced from the cantilever deflection data was e₃1=2.33±0.16 C/m² Sc concentration (30 mol % Sc). Thus, an increase in thickness does not cause deterioration of the piezoelectric coefficient. FIG. 23 shows a quasi-static (0.1 Hz), room temperature, stress vs electric field dependence for sample ASN1 (see Table 2) deposited on a Si wafer between upper and lower Ti electrical contacts. In-plane stress was quantitated by cantilever (substrate) deflection in response to an electric field applied perpendicular to the plane of the cantilever, along with knowledge of the mechanical properties of the wafer and thin films. We note that very weak 1-20 nA current is detected for 0.5-1.5 MV/m.

### Example 12

### XRD Spectra and Pole Figures of Textured (001) Ti and Cubic (111) TiN

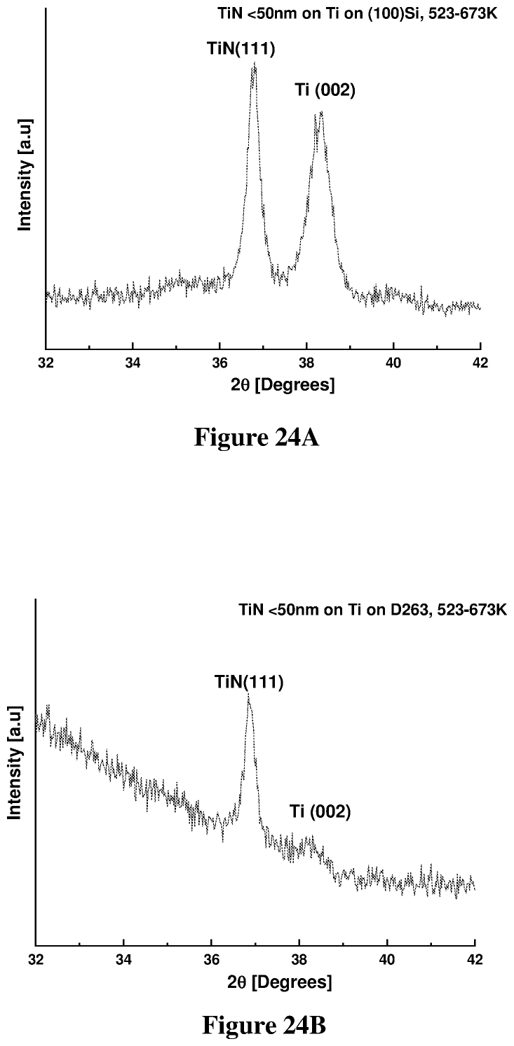

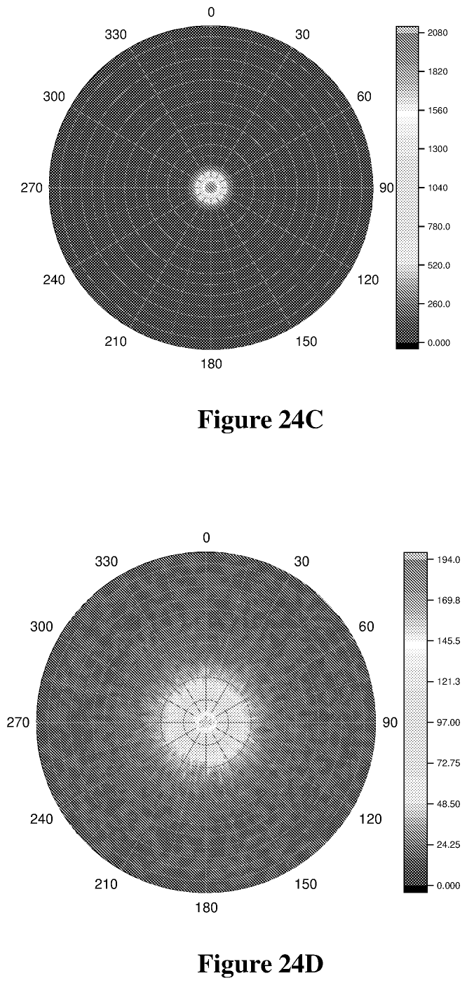

To verify the nature of TiN formation on (001) oriented Ti, TiN layers were deposited on Si and D263. The substrates were initially coated with the same Ti layers. Then, without breaking the vacuum, the substrates were heated in the sputtering chamber to 673±10 K and reactive DC sputtering from a metallic Ti was performed in 80/20% nitrogen/argon for 10 mins. Following a 10 min nucleation stage, deposition continued at 523K for another 10 mins. The resulting TiN films demonstrated preferred (111) texture (2 θ=36.8°) on the underlying Ti(002) film (FIGS. 24A and 24B). The pole figures of the corresponding Ti(002) and TiN(111) Bragg-Angle peaks backs this notion (FIGS. 24C and 24D). It should be noted that when the same TiN films were deposited on the substrate without the Ti seed, the resulted TiN films were non-oriented, highlighting the Ti importance.

### Example 13

### Deposition of Titanium Nitride

Titanium nitride films were deposited on 50 nm thick Ti on Si and D263 borosilicate glass. Substrate cleaning procedures were identical to those described above. Films were deposited with reactive DC sputtering at 150 W power applied to 2-inch (99.999% purity) Ti metal target (Abletarget, China). Chamber pressure was 5 mTorr; gas flow, 5 cc/min argon and 20 cc/min nitrogen. Deposition temperature was set to 623K for 10 min and then reduced to 523K for another 10 min.

### Example 14

### Deposition of 3 Um Tick Films of AlScN

A protocol for depositing 3 μm thick films of fully [001] textured Al₇₅,Sc₂₅N, is described herein. The procedure utilizes the fact that thin films of sputtered Ti are nearly 100% (001)-textured α-phase (HCP). Reaction between Ti and nitrogen plasma during reactive sputtering of (Al,Sc)N results in formation of <10 nm thick TiN seeding layers. Although TiN is too thin to be detected by XRD, its presence can be reliably detected by XPS. The fact that (001)-textured α-Ti is not a good substrate for Al₇₅,Sc₂₅N but the same film layer with TiN is, strongly suggests that TiN is (111) oriented. As a result, it decreases the lattice mismatch between the seeding layer and Al₇₅,Sc₂₅N to 3.7%. This supposition is supported by the fact that, in contrast to other reports, the Al₇₅,Sc₂₅N films prepared in the current study are oriented [001] rather than [001̅], which implies that the growth starts from a N-nitrogen layer.

An important advantage of the proposed technique is that it is applicable to a variety of substrates commonly used for actuators or MEMS, which prove to be compatible with deposition conditions, as demonstrated here for both Si wafers and D263 borosilicate glass.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

1. A process for the preparation of AlₓSc₁₋ₓN film, said process comprising:
a) providing a substrate;
b) producing a Ti first layer on said substrate;
c) depositing AlSc on said first layer; wherein said deposition is carried out in the presence of nitrogen gas, thus producing (AlSc)N layer, wherein a TiN layer in formed between said Ti first layer and between said (AlSc)N layer.

2. The process of claim 1, wherein steps (b)-(c) are performed by sputtering in a sputtering chamber.

3. (canceled)

4. (canceled)

5. (canceled)

6. (canceled)

7. The process of claim 1, wherein step (c) is carried out at a temperature ranging between 25° C. and 600° C.

8. (canceled)

9. The process of claim 1, wherein 0.57≤x≤1.

10. The process of claim 9, wherein said AlₓSc₁₋ₓN is Al_{0.50}Sc_{0.2} N or Al_{0.75}Sc_{0.25}N or Al_{0.7}Sc_{0.3}N.

11. The process of claim 1, wherein the thickness of said AlₓSc₁₋ₓN layer is greater than 0.8 μm.

12. The process of claim 1, wherein prior to step (b), said substrate is cleaned.

13. The process of claim 12, wherein said cleaning comprises the use of:
organic or inorganic solvent; and/or
organic or inorganic acid; and/or
gas plasma.

14. The process of claim 1, wherein:
step (b) is conducted at room temperature; and
step (c) is conducted at a temperature ranging between 25° C. to 400° C.

15. The process of claim 1, wherein:
step (b) is conducted under argon; and
step (c) is conducted under a gas further comprising argon.

16. The process of claim 15, wherein step (b) or step (c)-step-(d) or any combination thereof is conducted at a pressure lower than 1 atm.

17. The process of claim 1, further comprising producing a top layer comprising an electrically conductive material on said AlₓSc₁₋ₓN layer.

18. The process of claim 17, wherein the electrically conductive material is selected from Cu, Ag, Au, Pt, Pd, Ni, Al, Ta and Ti or a combination thereof.

19. The process of claim 18, wherein the top layer comprises Ti.

20. The process of claim 17, wherein said Ti first layer and said top layer are used as electrodes.

21. The process of claim 20, wherein said electrodes are independently connected to a power supply.

22. The process of claim 1, wherein the thickness of the combined Ti layer and TiN layer is between 50-300 nm.

23. A Ti/TiN layer made by the process of claim 1, wherein the thickness of the layer is between 50-300 nm.

24. An AlₓSc₁₋ₓN layer made by the process of claim 1.

25. (canceled)

26. A polycrystalline AlₓSc₁₋ₓN film wherein:
a. the orientation of said film is 001/002; or
b. the piezoelectric coefficient of said film ranges between 1.0 C/m² and 4.0 C/m²; or
c. the compressive stress of said film ranges between 5 MPa and 500 MPa; or
d. any combination thereof.

27. (canceled)

28. (canceled)

29. A piezoelectric device comprising:
a. a substrate;
b. a first Ti layer comprising Ti on said substrate;
c. TiN layer in contact with said Ti layer;
d. a layer comprising AlₓSc₁₋ₓN in contact with said TiN; and
e. a top layer comprising an electrically conductive material on said AlₓSc₁₋ₓN layer.

30. (canceled)

31. (canceled)

32. A cantilever comprising the AlₓSc₁₋ₓN layer of claim 1.

33. A micro electro-mechanical system (MEMS) comprising the AlₓSc₁₋ₓN layer of claim 1.
